(19) United States
(12) Patent Application Publication
(10) Pub. No.: US 2015/0075621 A1
(43) Pub. Date: Mar. 19, 2015

(54) Molecular Assemblies and Multilayer Films for Photocurrent and Catalysis

(71) Applicant: The University of North Carolina at Chapel Hill, Chapel Hill, NC (US)

(72) Inventors: Kenneth Hanson, Carrboro, NC (US); Thomas J. Meyer, Chapel Hill, NC (US)

(73) Assignee: THE UNIVERSITY OF NORTH CAROLINA AT CHAPEL HILL, Chapel Hill, NC (US)

(21) Appl. No.: 14/386,806

(22) PCT Filed: Mar. 20, 2013
(86) PCT No.: PCT/US2013/033140

§ 371 Date: Sep. 21, 2014

Related U.S. Application Data
(60) Provisional application No. 61/613,622, filed on Mar. 21, 2012.

(51) Int. Cl. H01G 9/20; H01L 51/00

(52) U.S. Cl. CPC H01G 9/2027; H01L 51/0086; H01L 51/0088; H01L 51/0091; H01L 51/0067; H01L 51/0092; H01L 51/0072; H01G 9/2059
USPC 136/263

(57) ABSTRACT

Some embodiments of the present invention provide an assembly for harvesting light, comprising a first molecule joined to a second molecule through mutual coordination to an ion, and the first molecule is linked to a metal oxide surface having a high surface area. Such assemblies can form multilayer films, in other embodiments. The assemblies and multilayer films can harvest light to do useful chemistry, such as in a dye-sensitized photoelectrochemical cell, or can convert the harvested light into electricity, such as in a dye-sensitized solar cell.

### CROSS REFERENCE TO RELATED APPLICATIONS

This international application claims benefit of priority to U.S. Provisional Patent Application No. 61/613,622, entitled, “MOLECULAR ASSEMBLIES AND MULTILAYER FILMS FOR PHOTOCURRENT AND CATALYSIS,” filed on Mar. 21, 2012, which provisional application is incorporated herein by reference in its entirety.

### STATEMENT REGARDING FEDERALLY-SPONSORED RESEARCH AND DEVELOPMENT

This invention was made with government support under Award No. DESC0001011 awarded by the Department of Energy. The government has certain rights in the invention.

### FIELD OF THE INVENTION

The present invention relates to harvesting light to do useful chemistry, in some embodiments. In other embodiments, the present invention relates to converting light into electrical current.

### BACKGROUND OF THE INVENTION

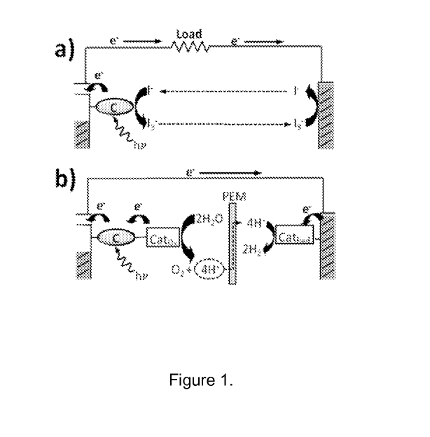

High surface area metal oxide electrodes coated with monolayers of chromophores are important to the operation of dye-sensitized solar cells (DSSCs) and dye-sensitized photo-electrochemical cells (DSPECs). In these devices, a small molecule dye known as a chromophore is bound to the surface of a semiconducting metal oxide electrode. See FIG. 1. In DSSCs (FIG. 1a), the chromophore (C) absorbs a photon of light (hv), and injects an electron (e⁻) into the metal oxide electrode also known as a photoanode. The electron enters the external circuit where it powers a device or charges a battery (Load). The oxidized chromophore is reduced by iodide (I⁻), which is oxidized to triiodide (I₃⁻). The circuit is then closed by electrons reducing triiodide (I³⁻) back to iodide (I⁻) at the cathode. Inventive DSSCs and components thereof are described below.

A DSPEC appears schematically in FIG. 1b. Similar to a DSSC, a chromophore (C) absorbs a photon of light (hv) and injects an electron (e⁻) into a semiconductor photoanode. An oxidation catalyst (Cat_{Ox}) reduces the oxidized chromophore back to its original state, and oxidizes a species in the electrolyte such as H₂0 to oxygen (O₂) and protons (H⁺). The electron that enters the external circuit is transferred to the cathode where it can be used by a reduction catalyst (Cat_{Red}) to reduce protons (H⁺), or CO₂ or other molecules (not shown). See FIG. 1b. Protons generated at the photoanode diffuse through a proton exchange membrane (PEM) to contact the reduction catalyst at the cathode. Oxygen (O₂) can be collected at the photoanode, while hydrogen (H₂) is collected at the cathode, in this example. The present disclosure describes examples of inventive DSPECs and components thereof.

One aspect of the operation of these devices is the initial light absorption and electron injection into the semiconductor material. Unlike a planar surface semiconductor where monolayer coverage results in less than 1% of the incident light being absorbed, the use of a high surface area nanocrystalline film increases the amount of dye that can be deposited and the light absorption can be greatly enhanced (>99% for a 10 μm thick film). The discovery and implementation of high surface area nanocrystalline TiO₂ by O'Regan and Gratzel marked the birth of a new class of solar cells based on dye-sensitization strategy.

It is generally true that higher light absorption will result in an increased the incident-photon to current efficiency. From this statement it could be assumed that making the nanocrystalline films very thick, in an effort to maximize light absorbance, would be advantageous. However, increased film thickness also results in decreases in photocurrent due to losses incurred during the electron transport through the semiconductor to the external circuit. Thus, in order to maximize the device performance, it is necessary to balance the chromophore loading (absorbed light) with the thickness of the nanocrystalline film (current losses).

A similar absorbance versus thickness issue arises when two different chromophores are deposited on an electrode. Since the surface area is a limiting factor, the codeposition of a second chromophore or catalyst on the surface decreases the quantity of the first chromophore and thus lowers the absorbance due to that species. The decreased absorbance can be supplemented by increasing the film thickness but the photocurrent losses mentioned above also will increase with film thickness.

Therefore, different strategies for maximizing light absorption while controlling or minimizing losses and other inefficiencies are needed.

### SUMMARY

Applicants have unexpectedly discovered molecular assemblies and multilayer films that harvest light for useful purposes, and methods of making and using them. As used herein, an assembly contains at least two molecules. A multilayer film contains at least two layers, in which one layer comprises a first molecule, and a second layer comprises a second molecule. In some cases, an assembly places in close proximity a first molecule that absorbs light, and a second molecule that does useful chemistry once the first molecule has absorbed light, without the need for the second molecule to diffuse to the first molecule. Similarly, in some cases, a multilayer film places in close proximity a layer containing a plurality of first molecules with a second layer containing a plurality of second molecules. One of the molecules absorbs light, and the other of the molecules does useful chemistry as a result. The close proximity is made possible, in certain cases, by coordinating the first molecule and second molecule to alike or different ions. In some instances, the molecules in an assembly exhibit enhanced electron transfer between them. In other instances, the molecules in an assembly exhibit enhanced energy transfer between them. In still other instances, the molecules in an assembly exhibit both enhanced electron transfer and enhanced energy transfer between them. Enhancement appears, in some cases, when the likelihood or rate of transfer is greater than if the molecules are unbound.

Accordingly, some embodiments of the present invention relate to an assembly for harvesting light, comprising: a surface comprising a metal oxide and having a high surface area; a first molecule linked to the surface through a surface-linking group, wherein the first molecule is a chromophore; and a second molecule, wherein the second molecule is chosen from chromophores, catalysts, and redox mediators; wherein the first molecule and the second molecule are joined via mutual coordination to an ion. In further embodiments, the first molecule is other than a chromophore, and the second molecule is a chromophore. For example, the first molecule can be, but is not limited to, catalysts and redox mediators when it is not a chromophore.

Other embodiments of the present invention relate to a multilayer film for harvesting light, comprising: a metal oxide exhibiting a high surface area; a first layer comprising molecules linked to the metal oxide via surface linking groups covalently bonded to the molecules; and one or more additional layers comprising molecules linked to the molecules of at least one other layer via mutual coordination to ions, which are alike or different; wherein the molecules, which are alike or different, are chosen from chromophores, catalysts, and redox mediators, wherein at least one of the layers comprises molecules that are chromophores.

Still other embodiments provide an electrode, for example, suitable for use in a dye-sensitized solar cell, or in a dye-sensitized photoelectrochemical cell, or both. Such an electrode can comprise an assembly for harvesting light, as described herein. Or such an electrode can comprise a multilayer film as described herein. The electrode can be adapted to act as a photoanode, collecting electrons during operation, and oxidizing a species contacting the electrode. Or, the electrode can be adapted to act as a photocathode, providing electrons during operation, and reducing a species contacting the electrode.

Further embodiments of the present invention provide a dye-sensitized solar cell that comprises an assembly for harvesting light. Still further embodiments provide a dye-sensitized solar cell that comprises a multilayer film for harvesting light. Other embodiments of the present invention provide a dye-sensitized photoelectrochemical cell that comprises an assembly for harvesting light. Yet other embodiments provide a dye-sensitized photoelectrochemical cell that comprises a multilayer film for harvesting light.

Applicants have also discovered additional methods for making and using the various embodiments of the present invention. Accordingly, still other embodiments of the present invention include a method of making an assembly for harvesting light, comprising: providing a surface comprising a metal oxide and having a high surface area; linking a first molecule, which comprises a surface-linking group and a first ion coordination group, to the surface via the surface-linking group; coordinating an ion with the first ion coordination group; coordinating a second ion coordination group to the ion, wherein the second ion coordination group is covalently bound to a second molecule, wherein at least one of the first molecule and the second molecule is a chromophore, thereby making the assembly for harvesting light.

Yet additional embodiments relate to a method for converting light into electrical current, comprising:

(a) providing a plurality of assemblies for harvesting light on a surface, wherein the assemblies are alike or different, and comprise a first molecule linked to the surface via a surface-linking group, a second molecule joined to the first molecule via mutual coordination to an ion, and wherein at least one of the first molecule and the second molecule is a chromophore; wherein the surface comprises a metal oxide and has a high surface area;
(b) illuminating the assemblies with light, thereby causing at least some of the assemblies to achieve an excited state and inject an electron into the metal oxide, thereby generating oxidized assemblies;
(c) reducing the oxidized assemblies in a manner that avoids or reduces electron transfer from the metal oxide to the oxidized assemblies, thereby converting light into electrical current.

Still further embodiments relate to a method for reacting a chemical species, comprising:

(a) providing a plurality of assemblies for harvesting light on a surface, wherein the assemblies are alike or different, and comprise a first molecule linked to the surface via a surface-linking group, a second molecule joined to the first molecule via mutual coordination to an ion, and wherein at least one of the first molecule and the second molecule is a chromophore; wherein the surface comprises a metal oxide and has a high surface area;
(b) placing a chemical species in reactive communication with the assemblies;
(c) illuminating the assemblies with light, thereby causing at least some of the assemblies to achieve an excited state and drive a reaction with the chemical species;
thereby reacting the chemical species.

These and other embodiments are described in greater detail in the description which follows.

### BRIEF DESCRIPTION OF THE DRAWINGS

The figures are not necessarily to scale, and should not be construed as limiting. Some details may be exaggerated to aid comprehension. An understanding of the figures can be had by reference to the detailed description that follows.

### DETAILED DESCRIPTION

The foregoing and other aspects of the present invention will now be described in more detail with respect to the description and methodologies provided herein. It should be appreciated that the invention can be embodied in different forms and should not be construed as limited to the embodiments set forth herein. Rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the embodiments of the invention and the appended claims, the singular forms “a”, “an” and “the” are intended to include the plural forms as well, unless the context clearly indicates otherwise. Also, as used herein, “and/or” refers to and encompasses any and all possible combinations of one or more of the associated listed items. Furthermore, the term “about,” as used herein when referring to a measurable value such as an amount of a compound, dose, time, temperature, and the like, is meant to encompass variations of 20%, 10%, 5%, 1%, 0.5%, or even 0.1% of the specified amount. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise defined, all terms, including technical and scientific terms used in the description, have the same meaning as commonly understood by one of ordinary skill in the art to which this invention belongs.

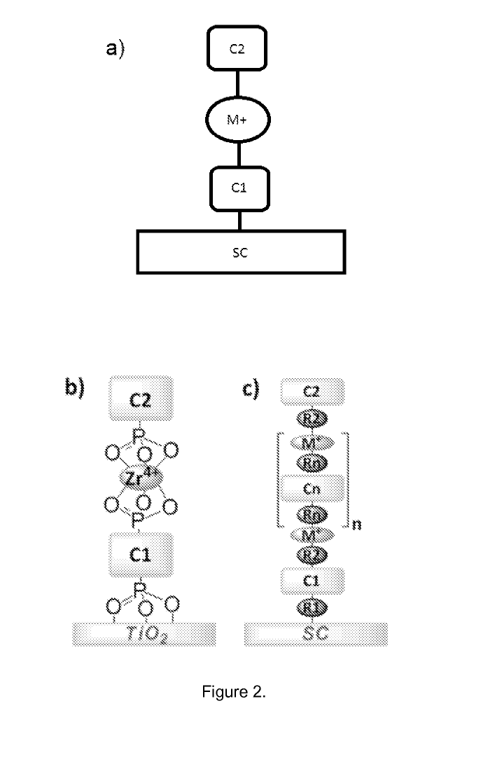

The present invention relates in some embodiments to an assembly for harvesting light. FIG. 2a shows a schematic illustration of such an assembly. SC represents a surface comprising a metal oxide and having a high surface area; C1 represents a first molecule linked to the surface through a surface-linking group; and C2 represents a second molecule. The first molecule and the second molecule are joined via mutual coordination to an ion, labeled M+ in the figure. In some cases, the first molecule is a chromophore, and the second molecule is chosen from chromophores, catalysts, and redox mediators. In other cases, at least one of C1 and C2 is a chromophore.

FIG. 2a shows, schematically, mutual coordination to one ion, but any suitable numbers of ions can be employed. In some embodiments, two, three, four, five, six, or more ions coordinate one or more first molecules to one or more second molecules. Also, each assembly need not coordinate the same ratio of first molecules to second molecules. Steric interactions and other factors may cause one first molecule to coordinate to just one second molecule, while another first molecule might coordinate to more than one second molecule. Also, as can be appreciated, one molecule may coordinate to more than one other molecule. In some embodiments, the ion is chosen from Cu²⁺, Co²⁺, Ni²⁺, Zn²⁺, Mn²⁺, Fe²⁺, Sr²⁺, Al³⁺, V³⁺, In³⁺, Fe³⁺, Gd³⁺, Y³⁺, Yb³⁺, Nd³⁺, Ce³⁺, La³⁺, Sc³⁺, Dy³⁺, Zr⁴⁺, Ti⁴⁺, Se, and combinations thereof. In certain embodiments, the ion is Zn²⁺. In certain other embodiments, the ion is Co²⁺. In still other embodiments, the ion comprises a zirconium ion. As used herein, the ion can be in any suitable form. In some cases, the ion has no detectable bond, ionic or otherwise, to any species other than to the molecules of the assembly. In other cases, the ion may be in the presence of one or more counter-ions and/or other compounds. For example, an oxygen anion or chloride anion could be found in proximity to a Zr⁴⁺ ion. In another example, one or more solvent compounds could coordinate to the ion as it joins the molecules of the assembly.

FIG. 2b schematically shows a titanium dioxide surface (TiO₂) with a first molecule (C1) anchored to the surface through a phosphonate surface linking group. The first molecule also contains a phosphonate ion coordination group, which coordinates to a Zr⁴⁺ ion. A second molecule (C2) also coordinates to the zirconium ion through a phosphonate ion coordination group. Molecules C1 and C2 are chosen from chromophores, catalysts, and redox mediators, provided at least one is a chromophore.

Additional embodiments provide an assembly further comprising a third molecule, chosen from chromophores, catalysts, and redox mediators, and the second molecule and the third molecule are joined via mutual coordination to an ion that is alike or different from the ion joining the first molecule and the second molecule. Any one of the second molecule and optional third molecule is chosen from catalysts, redox mediators, and combinations thereof, in additional embodiments. The number of molecules forming an assembly is not limited. In FIG. 2c, an assembly is shown that contains three or more molecules. A metal oxide semiconductor (SC) provides a surface on which a first molecule (C1) anchors to the surface through a surface linking group (R1). The first molecule coordinates to an ion (M⁺) through an ion coordination group (R2). The assembly also contains a number (n) of further molecules (Cn) which contain ion coordination groups (Rn). Each further molecule is linked into the assembly by coordinating to the ions (M+) present through the ion coordination groups (Rn). The assembly is terminated by a final molecule (C2) linked to the rest of the assembly through ion coordination group (R2). The number n can be any suitable integer, such as, for example, 1, 2, 3, 4, 5, 6, or more. In a collection of assemblies on a surface, n need not be the same for every assembly. The ions (M+), ion coordination groups (Rn), and further molecules (Cn) need not be identical, but can be alike or different.

Metal oxides useful in the present invention include any suitable metal oxides. In some embodiments, the metal oxide is chosen from SnO₂, TiO₂, Nb₂O₅, SrTiO₃, ZnO, Zn₂SnO₄, ZrO₂, NiO, Ta-doped TiO₂, Nb-doped TiO₂, and combinations of two or more thereof. In other embodiments, the metal oxide comprises TiO₂, such as nanocrystalline TiO₂. In further embodiments, the metal oxide comprises NiO. In still other embodiments, the surface comprises ZrO₂, such as nanoparticles of ZrO₂. Core-shell nanostructures are also possible, such as, for example, core-shell nanostructures comprising one or more of: ZnO-coated SnO₂, MgO-coated SnO₂, Al₂O₃-coated SnO₂, TiO₂-coated In-doped SnO₂, and TiO₂-coated F-doped SnO₂. Some instances provide a semiconducting surface. Other instances provide an insulating surface. Methods of making various metal oxide materials are known to those of ordinary skill in the art.

A high surface area means a surface area greater than a flat surface on the microscopic scale, such as is available on a single crystal. A high surface area can be achieved by any suitable means, such as, for example, by fusing particles together, or by etching a surface to introduce porosity. Some embodiments provide at least some of the metal oxide in the form of nanoparticles, nanocrystals, nanocolumns, nanotubes, nanosheets, nanoscrolls, nanowires, nanotips, nanoflowers, nanohorns, nano-onions, dendritic nanowires, or a combination of two or more thereof. Methods of making various forms of high surface area metal oxides are known to those of ordinary skill in the art. Examples of materials that may be suitable for some embodiments of the present invention appear in International Publication No. WO 2011/142848 to Corbea et al.

Surface linking groups include any suitable moieties. Sometimes, the surface linking group is chosen from —COOH, —PO₃H₂, —SO₃H, —OPO₃H, —OSO₃H, —SiR₃, -Ph(OH)₂, —CH(CO₂H)₂, —CH═C(CO₂H)₂, —CONHOH, —CSSH, —CSOH, and combinations thereof. The chemistry of derivatizing ligands such as 2,2′-bipyridine at the 4,4′-positions, for example, to include such moieties is known or is otherwise within the ordinary skill of artisans.

Catalysts useful in the present invention include any suitable catalysts. Suitable catalysts include, but are not limited to, single site water oxidation catalysts, multisite water oxidation catalysts, proton reduction catalysts, and combinations thereof. An example of a multisite water oxidation catalyst is the two-metal centered compound having the following structure:

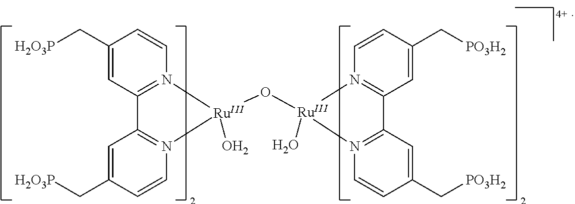

Deprotonated derivatives thereof also are contemplated. The foregoing compound can be synthesized analogously to the two-metal centered compound disclosed in S. W. Gersten, G. J. Samuels, and T. J. Meyer, J. Am. Chem. Soc. 1982, 104, 4029-4030. Phosphonation at the 4,4′ positions of the bpy ligands can be accomplished as reported in I. Gillaizeau-Gauthier, F. Odobel, M. Alebbi, R. Argazzi, E. Costa, C. A. Bignozzi, P. Qu and G. J. Meyer, Inorg. Chem., 2001, 40, 6073-6079. Some embodiments employ oxidation catalysts, which facilitate the oxidation of species in reactive communication with the catalyst. Other embodiments employ reduction catalysts, which facilitate the reduction of species in reactive communication with the catalyst. Catalysts suitable for use in certain embodiments of the present invention appear disclosed in U.S. Patent Application Publication No. US 2011/0042227 A1, to Corbea et al.

Suitable single site water oxidation catalysts, in some cases, comprise an atom of Ru, Co, Ir, Fe, or a combination thereof, when more than one such catalyst is present. In certain cases, the single site water oxidation catalyst is [Ru(2,6-bis(1-methylbenzimidazol-2-yl)pyridine)(4,4′-CH₂PO₃H₂-bpy)(OH₂)]²⁺ or a deprotonated derivative thereof.

Redox mediators that form part of the assemblies or thin films include any suitable redox mediators. Some cases provide

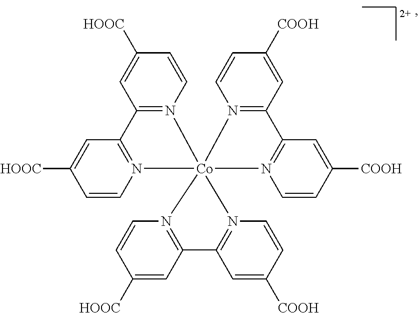

or a deprotonated derivative thereof, as a redox mediator.

Chromophores include any suitable species that harvest light to achieve an excited state. Metal-centered dye molecules appear in some embodiments. Certain additional embodiments provide assemblies or multilayer films in which any one of the first molecule, second molecule, and optional third molecule is chosen from ruthenium coordination complexes, osmium coordination complexes, copper coordination complexes, porphyrins, phthalocyanines, and organic dyes, and combinations thereof.

Suitable ruthenium coordination complexes include, but are not limited to:

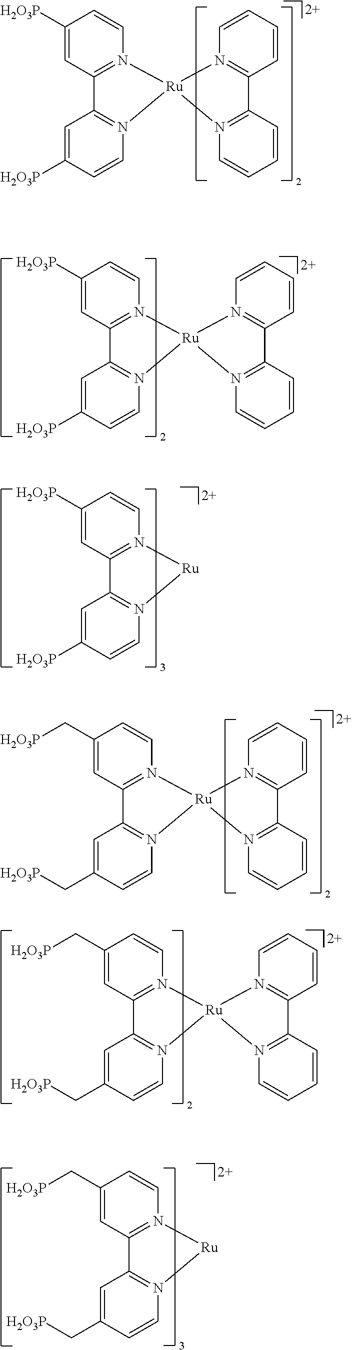

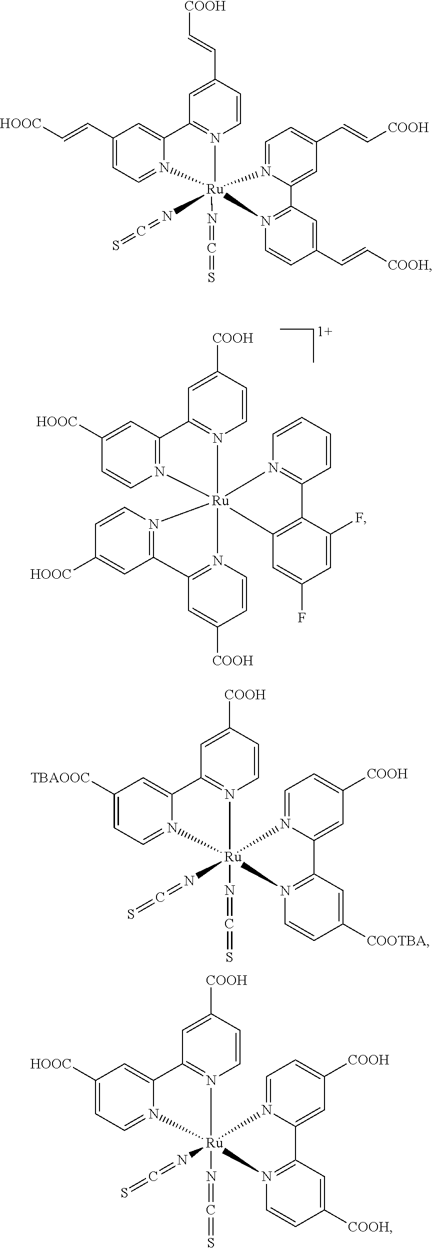

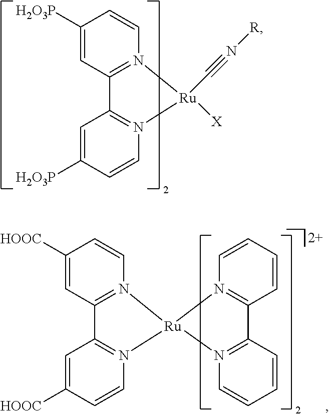

(X)₂bis(2,2′-bipyridyl-4,4′-dicarboxylate)ruthenium(II) compounds, wherein X is chosen from Cl, Br, I, CN, NC-Ph, and SCN;
deprotonated derivatives of any of the foregoing;
and combinations thereof.

Deprotonated derivatives of the molecules disclosed herein are those in which one or more hydrogen ions have been removed to form the conjugate base. It is believed, although not necessary for the practice of the present invention, that the conjugate base of certain surface linking groups and ion coordination groups represent the form of the molecule actually appearing in certain embodiments of the present invention. That is to say, the deprotonated form links to surface sites on the metal oxide, in some cases, while in other cases, the deprotonated form links to an ion joining two molecules together. One, two, three, four, five, six, or any suitable number of protons can be removed to form a deprotonated derivative. Methods for obtaining a deprotonated derivative are well known, such as, for example, by exposing the molecule to an increased pH, or by increasing the concentration of cations in solution.

Another embodiment of the present invention provides a first molecule such as

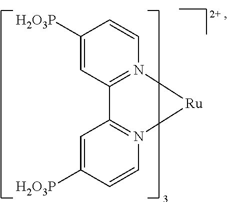

or a deprotonated derivative thereof. Other embodiments provide a first molecule comprising

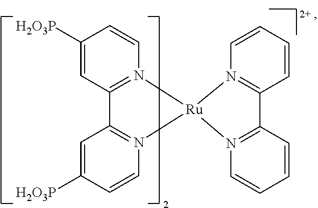

or a deprotonated derivative thereof. Still other embodiments provide a first molecule comprising

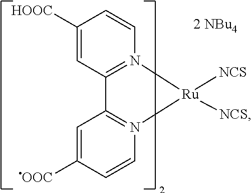

or a deprotonated derivative thereof.

Still additional embodiments provide a second molecule comprising

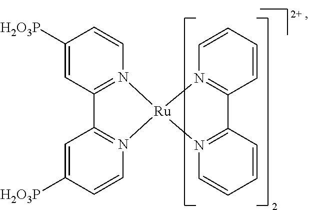

or a deprotonated derivative thereof. Other embodiments employ, as a second molecule,

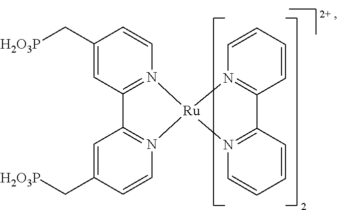

or a deprotonated derivative thereof. Further embodiments employ a second molecule comprising

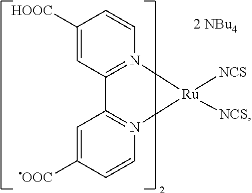

or a deprotonated derivative thereof. Still further embodiments provide a second molecule comprising [Ru(2,6-bis(1-methylbenzimidazol-2-yl)pyridine)(4,4′-CH₂PO₃H₂-bpy)(OH₂)]²⁺ or a deprotonated derivative thereof.

Some embodiments of the present invention employ osmium coordination complexes chosen from:

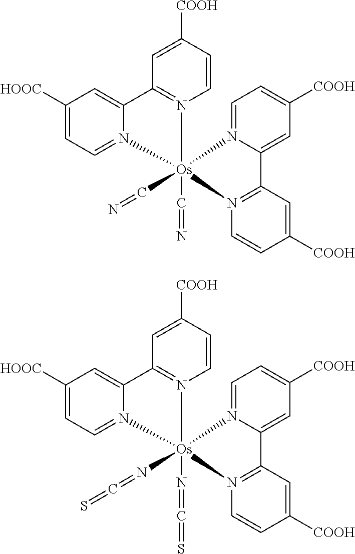

deprotonated derivatives thereof, and combinations thereof.

Other embodiments provide copper coordination complexes that are chosen from:

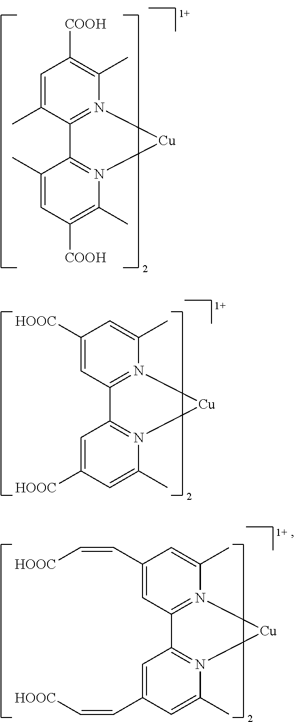

deprotonated derivatives thereof, and combinations thereof.

Still other embodiments employ porphyrins chosen from metal-coordination complexes comprising one of the following ligands:

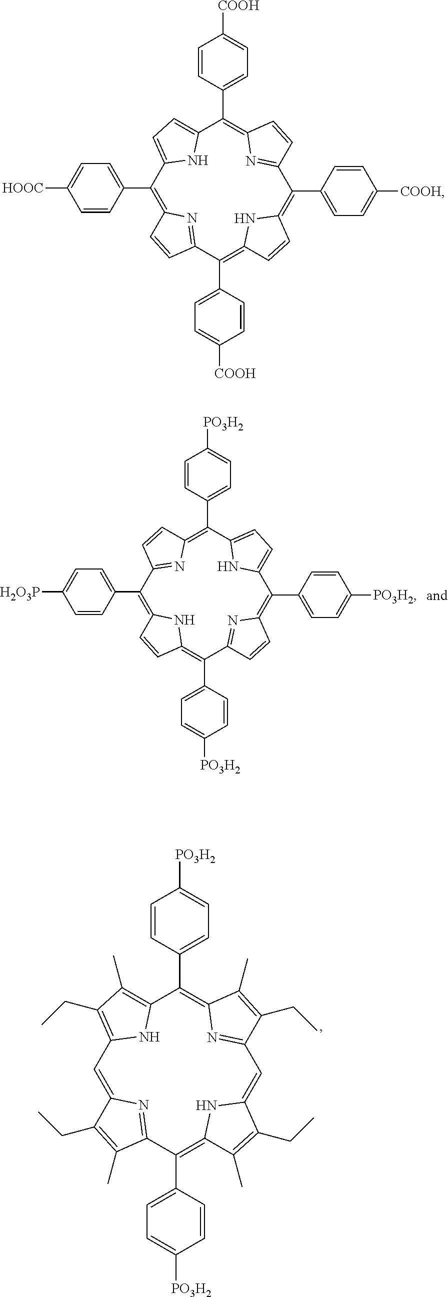

and deprotonated derivatives thereof. In some cases, the porphyrin is

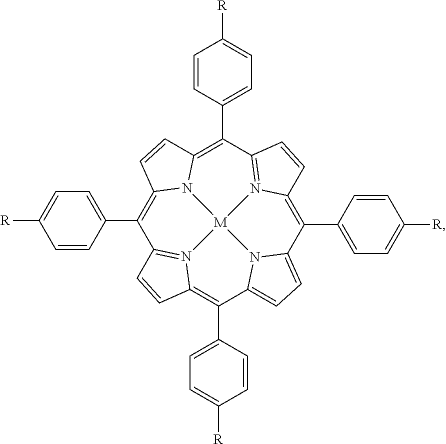

and M is Ni, Zn, Pd, Pb, Pt, or Ru, and R is chosen from —COOH, —PO₃H₂, or a deprotonated derivative thereof, or a combination of two or more of the foregoing. In some cases, the porphyrin is:

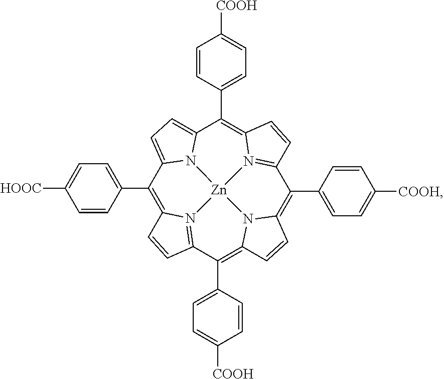

or a deprotonated derivative thereof.

Suitable phthalocyanines include, but are not limited to:

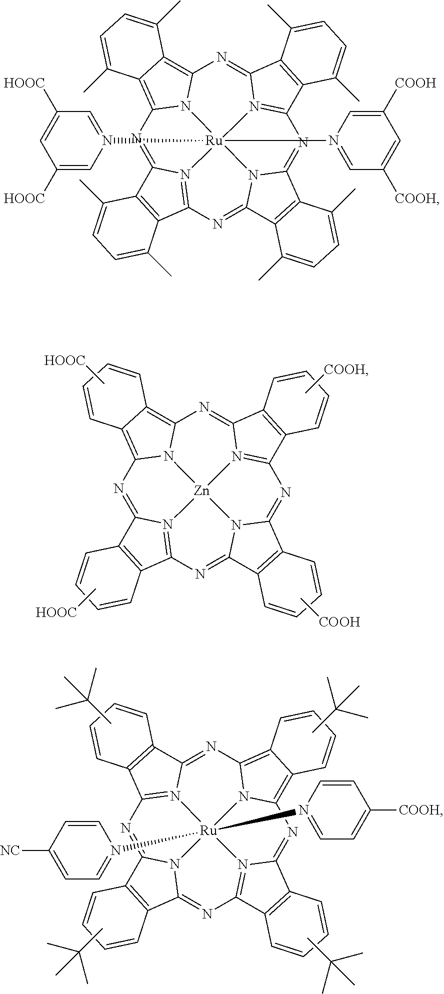

deprotonated derivatives thereof, and combinations thereof.

Organic dyes suitable for use in some embodiments of the present invention are chosen from:

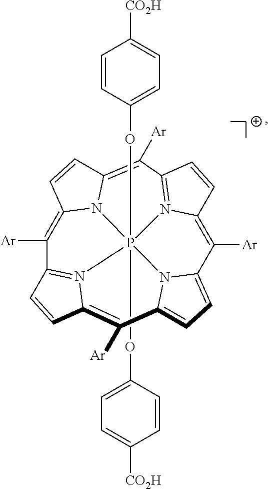

wherein Ar is 3,5-di-tertbutylphenyl;

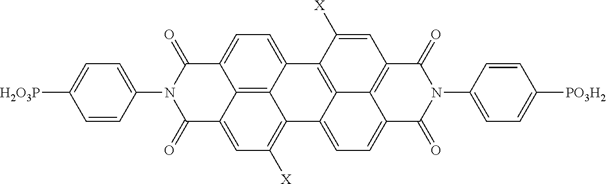

wherein X is halide, —CN, —CF₃, —CH₃, -Ph(CF₃)₂, Ph, Ph(CH₃)₂, or a combination thereof;
deprotonated derivatives thereof; and combinations thereof. As used herein, “Ph” relates to the phenyl group, C₆H₅—. Substituents can appear at any suitable position about the phenyl ring. When more than one substituent appears, they can be positioned in any suitable manner about the phenyl ring. In some cases, two substituents appear ortho, para to the carbon linking the phenyl ring to the rest of the molecule. In other cases, two substituents appear meta, meta to the linking carbon. In still other cases, two substituents appear in any suitable combination of ortho, meta, and/or para.

Synthesis of many of the first molecules and second molecules are known, and some are commercially available. Chemical modification of molecules, or of precursors thereof, to add the surface linking groups and ion coordination groups, is also known or can be obtained by analogy to known modifications. Other first molecules and second molecules can be selected and synthesized in accordance with the guidance provided herein.

First molecules join to second molecules (and second molecules to third molecules, and so on) by mutual coordination to an ion. Any suitable ion coordination groups can be used. They can be alike or different, both on a given molecule, and on molecules being joined. Suitable ion coordination groups include, but are not limited to —COOH, —PO₃H₂, —SO₃H, —OPO₃H, —OSO₃H, —SiR₃, -Ph(OH)₂, —CH(CO₂H)₂, —CH═C(CO₂H)₂, —CONHOH, —CSSH, —CSOH, and combinations thereof. Ion coordination groups can be incorporated into molecules according to any suitable method. For example, a ligand such as 2,2′-bipyridine can be modified at the 4-position, or at the 4,4′-positions, to add one or two ion coordination groups. The modified ligand can then coordinate to a metal ion, forming the molecule. Such synthetic methods are known.

Some embodiments of the present invention relate to multilayer films. Such multilayer films comprise, for example, a metal oxide exhibiting a high surface area; a first layer comprising molecules linked to the metal oxide via surface linking groups covalently bonded to the molecules; and one or more additional layers comprising molecules linked to the molecules of at least one other layer via mutual coordination to ions, which are alike or different; wherein the molecules, which are alike or different, are chosen from chromophores, catalysts, and redox mediators, wherein at least one of the layers comprises molecules that are chromophores. Thus, in some embodiments, a multilayer film can be thought of as a collection of many assemblies, wherein the first layer comprises first molecules, and an additional layer comprises second molecules.

Multilayer films can be made by any suitable method. For example, a metal oxide having a high surface area can be formed, followed by exposure to a composition containing a first molecule having a surface-linking group for a time sufficient to allow the first molecule to link to the surface, thereby forming the first layer. Then the first layer is exposed to a composition that allows the first layer to coordinate to ions that are alike or are different. A second molecule is introduced so that the second molecule can coordinate to the ions, thereby forming a second layer. The process of coordinating an ion, followed by coordinating a molecule to form a layer, can be repeated as many times as desired. In some cases, a multilayer film comprises two layers. In other cases, a multilayer film comprises 2, 3, 4, 5, or 6 layers. In still other cases, a multilayer film comprises 6-10 layers, or more than 10 layers.

Certain embodiments comprising multilayer films further comprise an outer layer comprising molecules linked to the molecules of an additional layer farthest from the metal oxide via mutual coordination to ions, wherein the molecules of the outer layer are chosen from catalysts and redox mediators.

Additional embodiments provide an electrode. Such an electrode can comprise at least one assembly for harvesting light, in some embodiments. Such an electrode can comprise a multilayer film for harvesting light, in other embodiments. Electrodes can comprise any suitable substrate for the assembly. In some cases, a substrate comprises a metal, such as, for example, copper, nickel, gold, silver, platinum, steel, glassy carbon, silicon, and alloys comprising one or more thereof. In other cases, the substrate is transparent or semitransparent to allow light to pass through the substrate to allow the assembly to harvest such light. Fluorine-doped tin oxide coated on glass, or indium-doped tin oxide on glass can be used in such cases.

Further embodiments provide a dye-sensitized solar cell. Such a cell can comprise at least one assembly for harvesting light, in some embodiments. Such a cell can comprise a multilayer film for harvesting light, in other embodiments. Suitable electrolyte compositions include those containing a desired redox mediator in a suitable solvent, for example. Suitable counter electrodes, cell arrangements, and other components of such dye-sensitized solar cells are known.

Still further embodiments provide a dye-sensitized photoelectrochemical cell. Such a cell can comprise at least one assembly for harvesting light, in some embodiments. Such a cell can comprise a multilayer film for harvesting light, in other embodiments. Suitable counter electrodes, cell arrangements, and other components of such dye-sensitized photoelectrochemical cells are known.

Further embodiments provide methods of making assemblies. In one example, a method of making an assembly for harvesting light, comprises providing a surface comprising a metal oxide and having a high surface area; linking a first molecule, which comprises a surface-linking group and a first ion coordination group, to the surface via the surface-linking group; coordinating an ion with the first ion coordination group; coordinating a second ion coordination group to the ion, wherein the second ion coordination group is covalently bound to a second molecule, wherein at least one of the first molecule and the second molecule is a chromophore, thereby making the assembly for harvesting light. Suitable metal oxide surfaces can be made or purchased, and then exposed to a composition such as a solution or suspension that contains the first molecule for a sufficient time for the first molecule to link to the surface through the surface-linking group. Then, the first molecule is exposed to conditions sufficient to cause an ion to coordinate to the first ion coordination group. Such conditions could include, for example, exposure to compositions containing a salt, optionally in the presence of an acid or a base, wherein the salt provides the ion. In another example, a molecule is reacted with zirconyl chloride (ZrOCl₂) to coordinate a Zr⁴⁺ ion to the ion coordination group of the first molecule. A second molecule is introduced, allowing the ion coordination group of the second molecule to coordinate to the ion, thereby forming the assembly.

First molecules, second molecules, ions, metal oxides, surface linking groups, ion coordination groups, and other components of the various embodiments of the present invention can be selected according to any suitable criteria. In certain embodiments, the first molecule and second molecule, and where present, the third molecule and any additional molecules, are chosen so that incident light will induce excited state electron transfer into the metal oxide. For example, an assembly on a photoanode could absorb a photon and inject an electron into the metal oxide, thereby generating a photocurrent and oxidizing a redox mediator in the electrolyte contacting the photoanode.

On the other hand, other embodiments provide the first molecule and second molecule chosen so that incident light will induce excited state electron transfer from the metal oxide. Similarly, where present, the third molecule and any additional molecules are also chosen so that incident light will induce excited state electron transfer from the metal oxide. For example, an assembly on a photocathode could absorb a photon and extract an electron from the metal oxide, thereby generating a photocurrent and reducing a redox mediator in the electrolyte contacting the photocathode.

Sometimes the first molecule and the second molecule are chosen so that incident light will induce oxidation, reduction, or catalytic reaction of a species in reactive communication with the assembly. Reactive communication means that a species, such as a molecule, can interact with the assembly optionally in the presence of other species to undergo chemical reaction. For example, H₂O in the presence of an assembly is in reactive communication when the assembly absorbs light, injects an electron into the metal oxide, and causes the H₂O to emerge in the form of O₂ or other oxidized form. The exact mechanism of any particular oxidation, reduction, or catalytic reaction is not limiting. In some cases, a species will covalently bond with a catalytic site on the assembly. In other cases, no covalent bond will form between the species and the assembly. Reactive communication includes the interaction between assemblies and unbounded redox mediators in the electrolyte composition when photocurrent is generated.

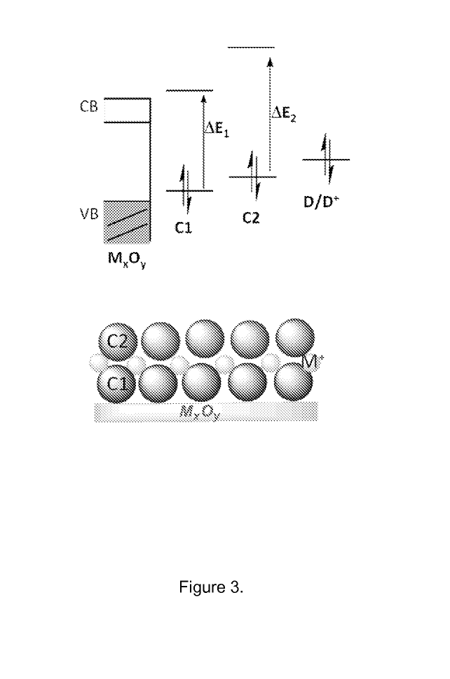

Selection of molecules for assemblies and multilayers will be aided by reference to FIGS. 3-6 as discussed below.

### Photoanode

When constructing an electrode intended to function as a photoanode, reference to FIG. 3 may illustrate some useful concepts. In one embodiment, a bilayer photoanode for a DSSC or DSPEC device comprises a high surface area metal oxide (MₓO_{y}) electrode with a valance band (VB) and conduction band (CB) covered with a monolayer of a first molecule (C1). The upper portion of FIG. 3 provides an energy diagram of MₓO_{y}, C1, a second molecule (C2), and an unbounded redox mediator couple or reaction substrate (D/D⁺). As shown in the lower part of FIG. 3, C2 is linked to C1 through mutual coordination to an ion M. M⁺ is chosen independently of MₓO_{y}. A plurality of C1 and plurality of C2 form a bilayer film.

If C1 is a chromophore in this embodiment, the lowest energy excited state of C1 achieved at an energy ΔE₁ above ground state results in electron transfer from C1 to the conduction band of MₓO_{y}. The excited state of C1 may be not sufficiently oxidizing to result in electron transfer from the VB of MₓO_{y} to C1.

The second molecule (C2) of the device can either be a 1) chromophore, 2) redox mediator, or 3) catalyst.

1) If C2 is a chromophore in a bilayer DSSC, it can be chosen such that the lowest energy excited state of C2 ΔE₂ above ground state) is of sufficient energy to result in energy transfer from C2 to C1. Additionally, a sufficient driving force for electron transfer from C2 to oxidized C1 is desired. The oxidation potential of C2 can be sufficient to result in electron transfer from the unbound redox mediator (D) to the oxidized C2. In such a bilayer film, electron transfer can occur through several mechanisms, depending on which chromophore absorbs a photon.
2) If C2 is a redox mediator in a bilayer DSSC, there can be sufficient driving force for electron transfer from C2 to oxidized C1. The oxidation potential of C2 can be sufficient to result in electron transfer from unbound redox mediator (D) to the oxidized C2.
3) If C2 is a catalyst in a bilayer DSPEC, the oxidation potential of C1 can be sufficient to drive all steps, through multiple excitation and electron transfer event, of the catalytic cycle of the catalyst (C2) such that C2 can oxidize reaction substrate D.

In some instances, it can be beneficial if ΔE₁≦ΔE₂. In other words, C1 can have an energy difference between the ground state and its lowest energy excited state that is less than or equal to that of C2. The lowest energy excited state represents the minimum energy level above the ground state from which useful chemistry can occur. Sometimes, the lowest energy excited state is a singlet state, or it can be a triplet state. From the lowest energy excited state useful chemistry occurs. That could mean electron transfer, such as electron transfer to a high surface area metal oxide. Or it could mean energy transfer, or oxidative or reductive chemical reaction, for example.

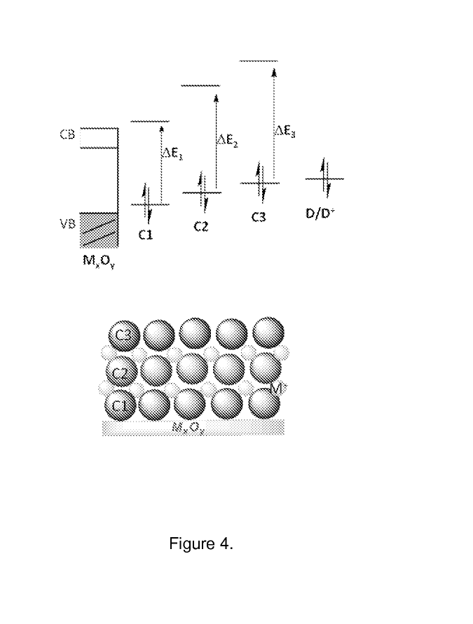

If a trilayer electrode intended to function as a photoanode is desired, reference to FIG. 4 may assist for some embodiments of the present invention. The lower portion of FIG. 4 shows a trilayer photoanode for a DSSC or DSPEC device comprising a high surface area metal oxide (MₓO_{y}) electrode with layers of a first molecule C1, a second molecule C2, and a third molecule C3. The layers are joined together by molecules mutually coordinating to ions (M⁺). The upper portion of FIG. 4 shows that MₓO_{y} exhibits a valance band (VB) and conduction band (CB) at energies relative to the energy levels of ground and lowest excited states for C1, C2, and C3. The lowest energy excited state of C1 (at energy ΔE₁ above ground state) results in electron transfer from C1 to the conduction band of MₓO_{y}. The excited state of C1 may be not sufficiently oxidizing to result in electron transfer from the VB of MₓO_{y} to C1.

The chromophore (C2) is such that the lowest energy excited state of C2 is of sufficient energy to result in energy transfer to C1. Additionally, there must be sufficient driving force for electron transfer from C2 to oxidized C1 in this embodiment.

The next component of the device C3 can either be a 1) chromophore, 2) redox mediator or 3) catalyst.

1) If C3 is a chromophore in a trilayer DSSC, it can be chosen such that the lowest energy excited state of C3 is of sufficient energy to result in energy transfer to C2. Additionally, there can be sufficient driving force for electron transfer from C3 to oxidized C2. The oxidation potential of C3 can be sufficient to result in electron transfer from the unbound redox mediator (D) to the oxidized C3.
2) If C3 is a redox mediator in a trilayer DSSC, C3 can be chosen so that there is sufficient driving force for electron transfer from C3 to oxidized C2. The oxidation potential of C3 can be sufficient to result in electron transfer from unbound redox mediator (D) to the oxidized C3.
3) If C3 is a catalyst in a trilayer DSPEC, the oxidation potential of C2 can be sufficient to drive all steps, through multiple excitation and electron transfer events, of the catalytic cycle of the catalyst (C3) such that C3 can oxidize reaction substrate D.

In some instances, it can be beneficial if ΔE₁≦ΔE₂, and ΔE₂≦ΔE₃. In other words, C1 can have an energy difference between the ground state and its lowest energy excited state that is less than or equal to that of C2. C2 can have an energy difference between the ground state and its lowest energy excited state that is less than or equal to that of C3.

### Photocathode

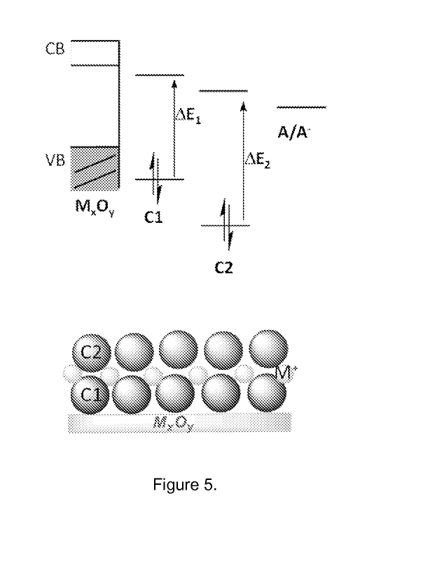

When a bilayer electrode intended to function as a photocathode is desired, reference to FIG. 5 may assist. As shown in the lower portion of FIG. 5, a bilayer photocathode for a DSSC or DSPEC device comprises a high surface area metal oxide (MₓO_{y}) electrode having a layer of a first molecule (C1) onto which binds a layer of a second molecule (C2) via mutual coordination to a plurality of ions (M+). The ions are chosen independently of the metal oxide. The upper portion of FIG. 5 shows an energy diagram, in which MₓO_{y} exhibits a valance band (VB) and conduction band (CB). Populating the lowest energy excited state of C1 (of energy ΔE₁ above ground state) results in electron transfer from VB to C1. The excited state of C1 is not sufficiently reducing to result in electron transfer from C1 to the CB of MₓO_{y}.

The next component of the device (C2) can either be a 1) chromophore, 2) redox mediator or 3) catalyst.
1) If C2 is a chromophore on a bilayer photocathode in a DSSC, C2 has a lowest energy excited state (ΔE₂ above ground state) of sufficient energy to result in energy transfer from C2 to C1. Additionally, there can be sufficient driving force for electron transfer from reduced C1 to C2. The reduction potential of C2 can be sufficient to result in electron transfer from reduced C2 to the unbound redox mediator (A).
2) If C2 is a redox mediator on a bilayer photocatalyst in a DSSC, there can be sufficient driving force for electron transfer from reduced C1 to C2. The reduction potential of C2 can be sufficient to result in electron transfer from the reduced C2 to unbound redox mediator (A).
3) If C2 is a catalyst on a bilayer photocathode of a DSPEC, the reduction potential of C1 can be sufficient to drive all steps, through multiple excitation and electron transfer events, of the catalytic cycle of the catalyst (C2) such that C2 can reduce reaction substrate A.

In some instances, it can be beneficial if ΔE₁≦ΔE₂. As stated above, C1 can have an energy difference between the ground state and its lowest energy excited state less than that of C2, in some cases. Or, C1 can have an energy difference equal to that of C2, in other cases.

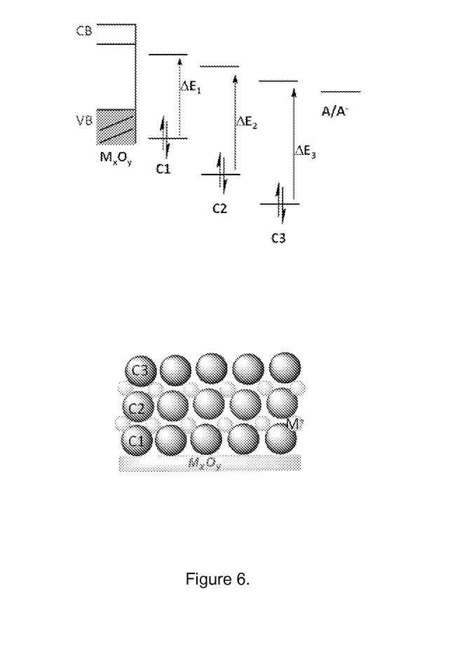

For a trilayer electrode intended to function as a photocathode in a DSSC or DSPEC, reference to FIG. 6 can be made. As shown in the lower portion of FIG. 6, a trilayer photocathode comprises a high surface area metal oxide electrode (MₓO_{y}) having layers of a first molecule (C1), a second molecule (C2), and a third molecule (C3), which layers are joined together by mutual coordination of the molecules to a plurality of ions (M⁺). The ions are chosen independently from the metal oxide. In this example, C1 and C2 are chromophores. The upper portion of FIG. 6 provides an energy diagram, showing MₓO_{y} having a valance band (VB) and conduction band (CB). The lowest energy excited state of C1 (of energy ΔE₁ above ground state) results in electron transfer from VB to C1. The excited state of C1 is not sufficiently reducing to result in electron transfer from C1 to the CB of MₓO_{y}.

The chromophore (C2) can be chosen so that the lowest energy excited state of C2 (of energy ΔE₂ above ground state) has sufficient energy to result in energy transfer to C1. Additionally, there can be sufficient driving force for electron transfer from reduced C1 to C2.

The next component of the device C3 can either be a 1) chromophore, 2) redox mediator, or 3) catalyst.

1) If C3 is a chromophore on a trilayer photocathode in a DSSC, C3 can be chosen so that the lowest energy excited state of C3 (of energy ΔE₃ above ground state) has sufficient energy to result in energy transfer from C3 to C2. Additionally, there can be sufficient driving force for electron transfer from reduced C2 to C3. The reduction potential of C3 can be sufficient to result in electron transfer from reduced C3 to an unbound redox mediator (A).
2) If C3 is a redox mediator on a trilayer photocathode for a DSSC, there can be sufficient driving force for electron transfer from reduced C2 to C3. The reduction potential of C3 can be sufficient to drive electron transfer from the reduced C3 to an unbound redox mediator (A).
3) If C3 is a catalyst on a trilayer photocathode for a DSPEC, the reduction potential of C2 can be sufficient to drive all steps, through multiple excitation and electron transfer events, of the catalytic cycle of C3 such that C3 can reduce reaction substrate A.

In some instances, it can be beneficial if ΔE₁≦ΔE₂, and ΔE₂≦ΔE₃. C1 can have an energy difference between its ground state and its lowest energy excited state that is less than that of C2, for example. Two or all of C1, C2, and C3 can have equal-magnitude energy differences, in another example.

Methods for converting light into electrical current also appear in certain embodiments of the present invention. Such a method might comprise

(a) providing a plurality of assemblies for harvesting light on a surface, wherein the assemblies are alike or different, and comprise a first molecule linked to the surface via a surface-linking group, a second molecule joined to the first molecule via mutual coordination to an ion, and wherein at least one of the first molecule and the second molecule is a chromophore; wherein the surface comprises a metal oxide and has a high surface area;
(b) illuminating the assemblies with light, thereby causing at least some of the assemblies to achieve an excited state and inject an electron into the metal oxide, thereby generating oxidized assemblies;
(c) reducing the oxidized assemblies in a manner that avoids or reduces electron transfer from the metal oxide to the oxidized assemblies, thereby converting light into electrical current. Alternatively, a dye-sensitized solar cell can be constructed in which electrons reduce excited chromophores or otherwise cause electrons to flow from the metal oxide. In some cases, light is harvested and converted into electricity in a manner analogous to that depicted in FIG. 1a. Referring to that figure, chromophore C would be replaced by an assembly of the present invention, in which at least one of the molecules of the assembly is a chromophore.

Further embodiments relate to methods for reacting a chemical species. Such a method might comprise, for example,

(a) providing a plurality of assemblies for harvesting light on a surface, wherein the assemblies are alike or different, and comprise a first molecule linked to the surface via a surface-linking group, a second molecule joined to the first molecule via mutual coordination to an ion, and wherein at least one of the first molecule and the second molecule is a chromophore; wherein the surface comprises a metal oxide and has a high surface area;
(b) placing a chemical species in reactive communication with the assemblies;
(c) illuminating the assemblies with light, thereby causing at least some of the assemblies to achieve an excited state and drive a reaction with the chemical species; thereby reacting the chemical species. Such a method is performed in a dye sensitized photoelectrochemical cell, for example, which has assemblies linked to a metal oxide surface having a high surface area, and a chemical species in the electrolyte solution in contact with the assemblies. The chemical species optionally bonds with an assembly, and undergoes chemical reaction when a molecule of the assembly achieves an excited state. The reaction can occur with the excited molecule, or with another molecule of the assembly. For example, a chromophore can absorb light and reach an excited state. Electron transfer, energy transfer, or another mechanism can activate a catalyst member of the assembly, thereby causing the chemical species to react. The exact reaction pathway is not limiting. In some cases, harvesting light to react a chemical species can proceed in a manner analogous to that depicted in FIG. 1b. In that figure, C and Cat_{Ox} are replaced by an assembly of the present invention that contains at least one chromophore and at least one oxidation catalyst.

Some embodiments provide a method of oxidizing water comprising:

(a) providing a plurality of assemblies for harvesting light on a surface, wherein the assemblies are alike or different, and comprise a first molecule linked to the surface via a surface-linking group, a second molecule joined to the first molecule via mutual coordination to an ion, and wherein the first molecule is a chromophore and the second molecule is a water oxidation catalyst; wherein the surface comprises a metal oxide and has a high surface area;
(b) placing water in reactive communication with the assemblies;
(c) illuminating the assemblies with light, thereby causing at least some of the assemblies to achieve an excited state and drive an oxidation reaction with the water; thereby oxidizing the water. In some instances, the second molecule is a single site water oxidation catalyst. In other instances, the second molecule is a multisite water oxidation catalyst.

### INDUSTRIAL APPLICABILITY

The various embodiments of the present invention are susceptible to industrial exploitation in the realms of energy production, energy storage, and chemical synthesis. For example, light can be converted into electrical current, in some embodiments. In other embodiments, energy can be stored in the form of oxygen on the one hand, and hydrogen, methane, other hydrocarbon, or other fuel on the other hand. Useful chemicals can be synthesized by the photocatalytic effect available to certain embodiments. Other aspects of industrial applicability can be discerned by reference to the specification and claims.

The present invention will now be described in more detail with reference to the following examples. However, those examples are given for the purpose of illustration and are not to be construed as limiting the scope of the invention.

### EXAMPLES

### Experimental

### Chromophores.

Certain chromophores will be referred to herein as follows:

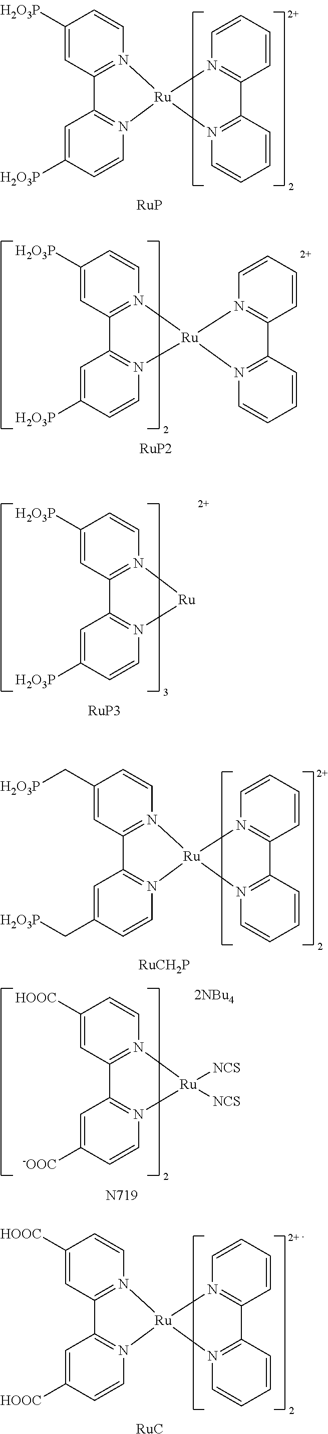

Also, as used herein, bpy means 2,2′-bipyridine.

### Sample Preparation.

Materials. Aqueous solutions were prepared from water purified by use of a MilliQ purification system. Zirconyl chloride octahydrate, lithium Iodide, 70% perchloric acid (99.999% purity), chloroplatinic acid (H₂PtCl₆), titanium isopropoxide, zirconium isopropoxide, and Carbowax 20M were used as received from Sigma-Aldrich. Fluorine-doped tin oxide (FTO) coated glass (Hartford Glass Co.; sheet resistance 15 Ωcm⁻²), was cut into 11 mm×50 mm strips and used as the substrate for ZrO₂ or TiO₂ nanoparticle films. The dye known as N719 was purchased and used without further purification from Solaronix. All other ruthenium complexes were prepared according to literature procedure.

Thin Films.

Nano-TiO₂ films and nano-ZrO₂ films, 4.5 or 7.0 μm thick, coating an area of 11 mm×25 mm on top of FTO (fluorine-doped In₂O₃) glass were prepared according to previously published procedures. Monolayer films and the first layer of the bilayer films were loaded overnight from solutions of 150 μM ruthenium complexes in 0.1 M HClO₄ aqueous solution for the phosphonate derivatized complexes, from 0.3 M N719 in acetonitrile or 150 μM of RuC in methanol. The films were then rinsed with methanol and dried under a stream of nitrogen. Samples for bilayer films were then submerged for 60 minutes in 0.5 M ZrOCl₂.8H₂O in methanol and 0.1 M HClO₄ for carboxylate and phosphonate monolayers respectively. Dye adsorption isotherms of the bilayer films was achieved by immersing the TiO₂ thin films in 3 mL of 0.1 M HClO₄ aqueous solutions of RuP with concentrations of 10, 20, 50, 100, 150 and 200 μM. Samples were soaked an additional 12 hours in 0.1 M HClO₄ to remove any excess ruthenium complex. Upon completion, the slides were removed from solution, rinsed with methanol and dried under a stream of nitrogen. Absorption spectra were obtained by placing the dry derivatized TiO₂/FTO slides perpendicular to the detection beam path. For the bilayer films, the absorption spectra of the first layer were subtracted from the bilayer absorbance. Surface coverages (Γ in mol cm⁻²) were estimated with the expression Γ=A(λ)/ε(λ)/1000. In these analyses, molar extinction coefficients (ε) for the complexes in 0.1 M HClO₄ aqueous solution, and A(λ) was the absorbance of second layer. The adduct formation constant (K_{ad}) and maximum surface (Γₘₐₓ) coverage of TiO₂—Ru^{II}P were obtained using the Langmuir isotherm model (Γ=Γₘₐₓ ((K_{ad}[Ru^{II}P])/(1+K_{ad} [Ru^{II}P]))). Theoretical maximum monolayer coverages, Γₒ=Γₘₐₓ=1.4×10⁻⁷ mol cm⁻², were calculated based on TiO₂ particle size (17.5 nm) and film thickness (7.0±0.1 μm).

### Electrochemical and Photophysical Characterization.

Absorption spectroscopy.

The UV-visible spectra were recorded using an Agilent 8453 UV-Visible photo diode array spectrophotometer (adsorption isotherms), a Varian Cary 5000 UV-Vis-NIR spectrophotometer (spectroelectrochemistry) or a Varian Cary 50 UV-Vis spectrophotometer (photostability).

Steady-State and Time-Resolved Emission.

Steady-state emission spectra were collected using an Edinburgh FLS920 spectrometer with a 450 W Xe lamp excitation source and R2658P photomultiplier tube as the detector. Quantum efficiency measurements were carried out on the same system with an Edinburgh integrating sphere accessory. Time-resolved emission measurements were conducted using the time-correlated single-photon counting technique on the FLS920 system with the Edinburgh EPL-445 picosecond pulsed diode laser (444.2 nm) as the excitation source.

Electrochemical Characterization.

Cyclic voltammetry (CV) and spectroelectrochemical measurements were performed using a CH Instruments Model 600D Series Electrochemical Workstation with ruthenium compound derivatized TiO₂/FTO slides as the working electrode, a platinum wire counter electrode and a Ag/AgCl reference electrode (BASi). All measurements were performed in 0.1 M HClO₄ aqueous solution. CV traces were collected at a scan rate of 10 mV/s. Surface electron transfer measurements were performed by monitoring changes in absorption at 490 nm using a Cary 5000 UV-Vis spectrophotometer during the application of 1.5 V for 10 minutes followed by 0 V for 10 minutes.

Transient Absorption.

All spectroscopic measurements, other than adsorption isotherms, were carried out by inserting derivatized thin films at a 45° angle into a standard 10 mm path length square cuvette containing 0.1 M HClO₄ aqueous solutions. The top of the cuvette was fit with an o-ring seal with a Kontese valve inlet to allow the contents to be purged with Argon. Transient absorption (TA) experiments were performed by using nanosecond laser pulses produced by a Spectra-Physics Quanta-Ray Lab-170 Nd:YAG laser combined with a VersaScan OPO (532 nm, 5-7 ns, operated at 1 Hz, beam diameter 0.5 cm, ˜5 mJ/pulse) integrated into a commercially available Edinburgh LP920 laser flash photolysis spectrometer system. White light probe pulses generated by a pulsed 450 W Xe lamp were passed through the sample, focused into the spectrometer (3 nm bandwidth), then detected by a photomultiplier tube (Hamamatsu R928). Appropriate color filters were placed before the detector to reject unwanted scattered light. Detector outputs were processed using a Tektronix TDS3032C Digital Phosphor Oscilloscope interfaced to a PC running Edinburgh's software package. Single wavelength kinetic data were the result of averaging 50 laser shots and were fit using either Origin or Edinburgh software.

X-Ray Photoelectron Spectroscopy.

X-ray photoelectron spectra (XPS) were obtained at the Chapel Hill Analytical and Nanofabrication Lab (CHANL) at UNC. A Kratos Analytical Axis UltraDLD spectrometer with monochromatized X-ray Al Kα radiation (1486.6 eV) with an analysis area of 1 mm² was used. A survey scan was first performed with a step size of 1 eV with a pass energy of 80 eV. High resolution scans were then taken for each element present with a step size of 0.1 eV and a pass energy of 20 eV. The binding energy for all peaks was referenced to the C 1s peaks at 284.6 eV. Peaks such as the Ru 3d and C 1s were fit using a Gaussian-Lorentzian curve fit with a Shirley background subtraction. Quantitative data was obtained by using empirical relative sensitivity factors.

Attenuated Total Reflectance Infrared Spectroscopy.

Attenuated total reflectance (ATR) IR spectra were recorded using a Bruker Alpha FTIR spectrometer (SiC Glowbar source, DTGS detector) with a Platinum ATR quickSnap sampling module (single reflection diamond crystal). Spectra were acquired from 800 to 1800 cm⁻¹ at a resolution of 4 cm⁻¹. All ATR-IR spectra are reported in absorbance with a blank versus atmosphere.

Photo-Stability Studies.

All photostability measurements were performed using previously reported procedure. The light from a Royal Blue (455 nm, FWHM ˜30 nm, 475 mW/cm²) Mounted High Power LED (Thorlabs, Inc., M455L2) powered by a T-Cube LED Driver (Thorlabs, Inc., LEDD1B) was focused to a 2.5 mm diameter spot size by a focusing beam probe (Newport Corp. 77646) outfitted with a second lens (Newport, Corp 41230). Light output was directed onto the derivatized thin films placed at 45° in a standard 10 mm path length cuvette containing 5 mL of the solutions of interest. The illumination spot was adjusted to coincide both with the thin films and the perpendicular beam path of a Varian Cary 50 UV-Vis spectrophotometer. The absorption spectrum (360-800 nm) of the film was obtained every 15 minutes during 16 hours of illumination. The incident light intensity was measured using a thermopile detector (Newport Corp 1918-C meter and 818P-020-12 detector). The solution temperature, 22±2° C., was consistent throughout the duration of the experiment.

### Results

### Monolayer Film Characterization.

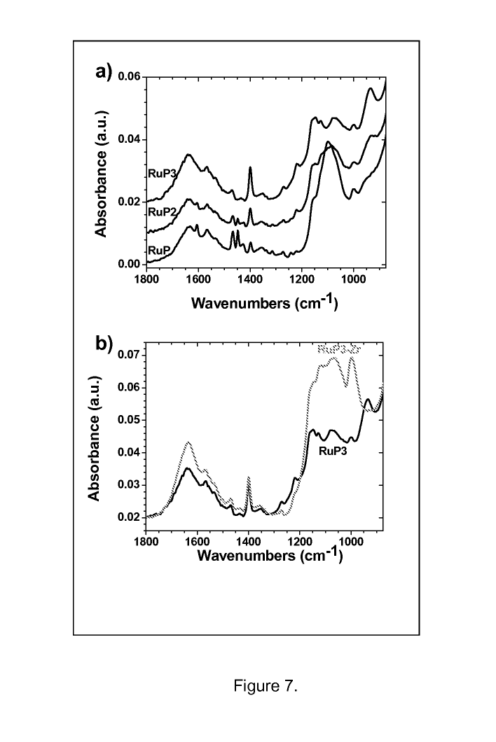

Monolayer films of RuP, RuP2 and RuP3 on TiO₂ were prepared by submerging 7 μm thick TiO₂ slides in a 150 μM concentration of the complexes in 0.1 M HClO₄ aqueous solution overnight. The ATR-IR spectrum of RuP, RuP2 and RuP3 monolayers on TiO₂ can be seen in FIG. 7a. Several transitions due to 2,2′-bypridine (bpy) (1605, 1466 and 1446 cm⁻¹) and 4,4′-(PO₃H₂)₂(bpy) (1398 cm⁻¹) ring breathing modes can be observed with intensities proportional to the number of substituted or unsubstituted bpy ligands. Broad absorption from 1000-2000 cm⁻¹ are due to both uncoordinated and surface bound P═O, P—O and PO₃ stretching modes. The non-surface-bound phosphonates have a characteristic P-0 stretch at 935 cm⁻¹. This assignment is further supported absence of this peak in RuP which presumably has both phosphonate groups bound to the surface, and an increase in intensity at 935 cm⁻¹ from RuP2 to RuP3.

Upon submersion of the TiO₂—RuP3 slide in the 5 mM ZrOCl₂ in 0.1 M HClO₄ aqueous solution for 1 hour, the free phosphonate P-0 stretching mode at 935 cm⁻¹ decreases concurrently with an increase in absorption intensity from 1000-2000 cm⁻¹ and a new peak at 996 cm⁻¹ (FIG. 7b). The shift in absorption from 935 to 996 cm⁻¹ is indicative of the coordination of phosphonate groups to metal ions. The complete disappearance of the 935 cm⁻¹ peak suggests that all of the non-surface bound phosphonate moieties are coordinated to at least one Zr⁴⁺ after soaking in ZrOCl₂. The Zr⁴⁺ loading process is complete in less than 20 minutes of soaking since no further changes in the infrared absorbance spectrum was observed after this time.

The XPS data for TiO₂—RuP3 slides soaked in ZrOCl₂ for one hour indicate that there is ˜4.2:1 ratio of zirconium to ruthenium. A Zr to Ru ratio of 4:1 is expected if every free phosphonate is coordinated to a single zirconium ion suggesting that this is in fact the case.

### Bilayer Film Characterization.

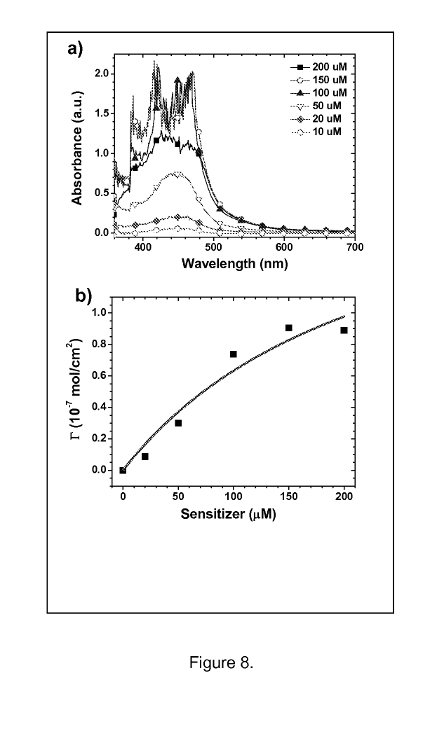

Bilayers of the ruthenium chromophores were obtained in a stepwise manner by submerging TiO₂ films in 1) 150 μM of RuP3 in 0.1 M HClO₄ aqueous solution overnight, 2) 5 mM ZrOCl₂ in 0.1 M HClO₄ aqueous solution for 1 hour and finally 3) RuP in 0.1 M HClO₄ aqueous solution overnight. Adsorption isotherms for the second layer were acquired by submerging the TiO₂—RuP3-Zr slides in 3 mL of 20, 50, 100, 150 and 200 μM of RuP in 0.1 M HClO₄ solutions. The absorption spectrum for the RuP layer (FIG. 8a) was obtained by subtracting the absorbance by the first RuP3 layer. Due to the approximately two fold increase in absorbance for the films loaded from 100, 150 and 200 mM solutions, the absorbance spectra below 480 nm in FIG. 8a are beyond the detection limit of the UV-Vis spectrometer. However, the absorbance at 500 nm could readily be used to calculate surface coverages (Γ in mol cm⁻²) with the expression Γ=A(λ)/ε(λ)/1000 where ε and A are the molar absorptivities and absorbance, respectively, at 500 nm (FIG. 8b).

From the absorption isotherms (FIG. 8b), the adduct formation constant (K_{ad}) and maximum surface (Γₘₐₓ) coverage of the RuP bilayer was obtained using the Langmuir isotherm model (Table 1). The maximum surface coverage for the bilayer film (2.1×10⁻⁷ mol cm⁻²) is comparable to the values found for RuP and RuP3 monolayers (1.6 and 1.7×10⁻⁷ mol cm⁻²) as well as the calculated maximum (1.4×10⁻⁷ mol cm⁻²) assuming a 14 Å diameter chromophore, TiO₂ particle size (17.5 nm) and film thickness (7.1±0.1 μm). The adduct formation constant for RuP on TiO₂—RuP3-Zr (>4,000 M⁻¹) was lower than that of RuP and RuP3 (>14,000 M⁻¹) directly on TiO₂, presumably due to a decreased number of metal ion binding sites for RuP on the RuP3-Zr film compared to TiO₂.

TABLE 1
The surface coverage and formation constant for RuP, RuP3 and the
RuP3-Zr—RuP bilayer films on TiO₂.

| | ┌ × 10⁻⁷ | K_{ad} × 10⁴ |
|---|---|---|
| Complex | (mol cm⁻²) | (M⁻¹) |
| RuP | 1.6 | 1.7 |
| RuP3 | 1.7 | 1.4 |
| RuP3-Zr—RuP | 2.1 | 0.4 |

These results suggest that the second chromophore treatment after ZrOCl₂ results in the formation of a second monolayer that obeys Langmuir isotherm model on top of the TiO₂—RuP3-Zr film. This result is further supported by the approximately two fold increase in absorbance for films loaded for >100 μM RuP.

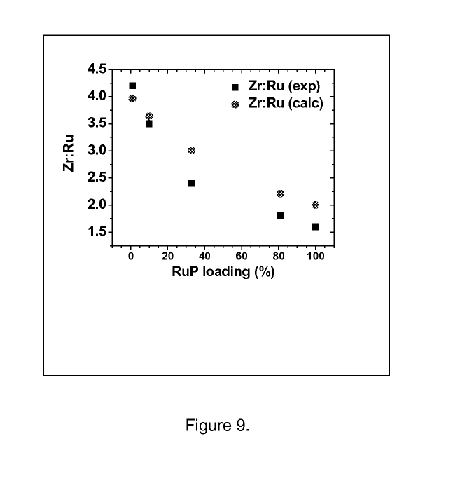

The films prepared for isotherm measurements were further characterized by XPS and the results are summarized in Table 2. For each slide, two XPS spectra were obtained, and the relative atomic concentrations of ruthenium and zirconium were determined using empirical relative sensitivity factors. As mentioned above, the average Zr to Ru concentration for the monolayer films with ZrOCl₂ treatment is 4.2 to 1. As the percent loading of the second layer increases there is an increase and decrease in the relative concentration of ruthenium and zirconium respectively. Assuming that the ˜4:1 (Zr:Ru) concentration is maintained for the TiO₂—RuP3-Zr films after soaking, then the calculated Zr to Ru ratio can be calculated based on the percent coverage of the RuP layer. A comparison of the calculated and experimentally determined Zr:Ru can be seen in FIG. 9. The figure shows the calculated (circle) and experimental (square) zirconium to ruthenium ratio for bilayer films of TiO₂—RuP3-Zr—RuP. The values are in relatively good agreement with a slightly lower (1.6) than expected (2.0) ratio as the percent loading of RuP increases. The lower concentration of Zr for the experimental value may be at least partially due to the slightly lower depth of penetration of the x-rays into the bilayer film. Here in all bilayer films are loaded from 150 μM solutions of the chromophore to ensure maximum surface coverage.

TABLE 2
The atomic concentrations and zirconium to ruthenium
ratio (Zr:Ru) found by XPS for bilayer films prepared from various
concentrations of RuP on TiO₂—RuP3—Zr.

| [RuP] | % | [Ru] | [Zr] | | Average | Calc |
|---|---|---|---|---|---|---|
| μM | Loading | (%) | (%) | Zr:Ru | Zr:Ru | Zr:Ru |
| 0 | 0 | 0.60 | 2.46 | 4.10 | 4.2 | 4.0 |
| | | 0.55 | 2.34 | 4.25 | | |
| 20 | 10 | 0.69 | 2.30 | 3.33 | 3.5 | 3.6 |
| | | 0.64 | 2.37 | 3.7 | | |
| 50 | 33 | 0.82 | 1.79 | 2.18 | 2.4 | 3.0 |
| | | 0.81 | 2.09 | 2.58 | | |
| 100 | 81 | 1.01 | 1.78 | 1.76 | 1.8 | 2.2 |
| | | 1.04 | 1.84 | 1.77 | | |
| 150 | 100 | 1.10 | 1.69 | 1.54 | 1.6 | 2.0 |
| | | 1.08 | 1.69 | 1.56 | | |

### Emission.

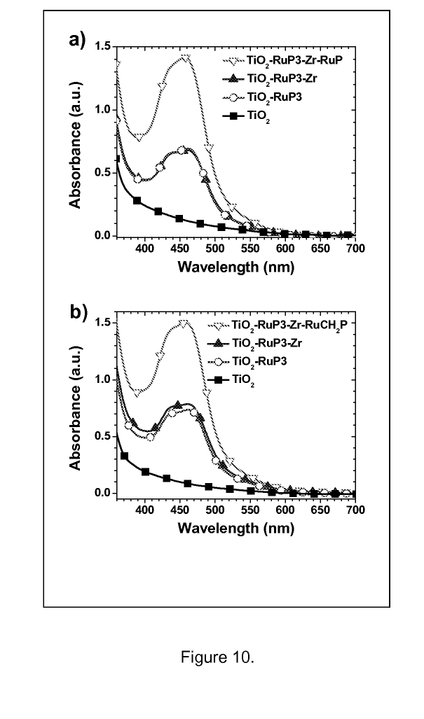

In some embodiments, there can be energy and electron transfer between the two layers of a bilayer film. To demonstrate energy and electron transfer, two bilayer films were prepared: RuP3-Zr—RuP (1) and RuP3-Zr—RuCH₂P (2) on TiO₂ and ZrO₂. Films 1 and 2 were prepared on ˜4.5 μm-thick TiO₂ to ensure transmission of the incident light for transient absorption measurements. The absorption spectra of TiO₂-1 and TiO₂-2 after every step in the multilayer deposition process can be seen in FIG. 10. Nominal changes in absorption were observed upon the addition of Zr⁴⁺ to the TiO₂—RuP3 films. The addition of RuP (FIG. 10a) and RuCH₂P (FIG. 10b) to the monolayer films results in an approximately two fold increase in absorption from 350-600 nm as expected for a bilayer film composed of ruthenium polypyridyl complexes with similar extinction coefficients.

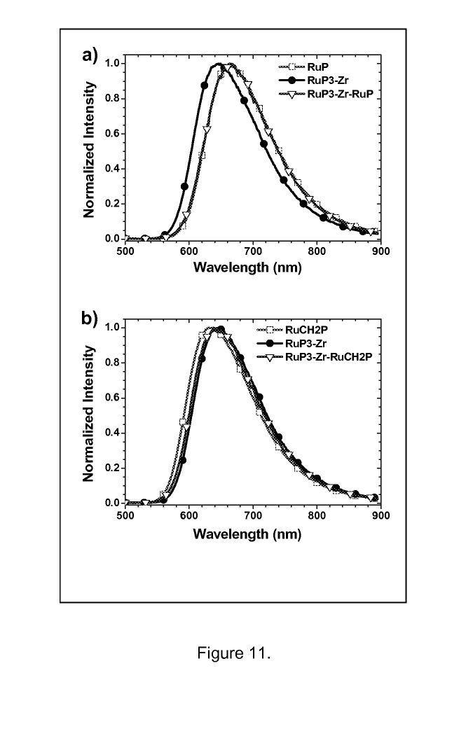

It has been previously noted that emission from RuP on TiO₂ is less than 1% of that on ZrO₂ in 0.1 M HClO₄ due to the electron transfer quenching by TiO₂, a process that is inhibited on ZrO₂ by its more negative conduction band of ZrO₂ (˜1.4 V vs. NHE, pH=7).³⁰ In order to investigate energy transfer within the bilayer film without the complications associated with electron transfer, 1 and 2 were prepared on ˜7 μm-thick ZrO₂ films. A comparison of the emission spectra of ZrO₂-1 and ZrO₂-2 to their parent chromophores RuP, RuCH₂P and RuP3-Zr can be seen in FIG. 11.

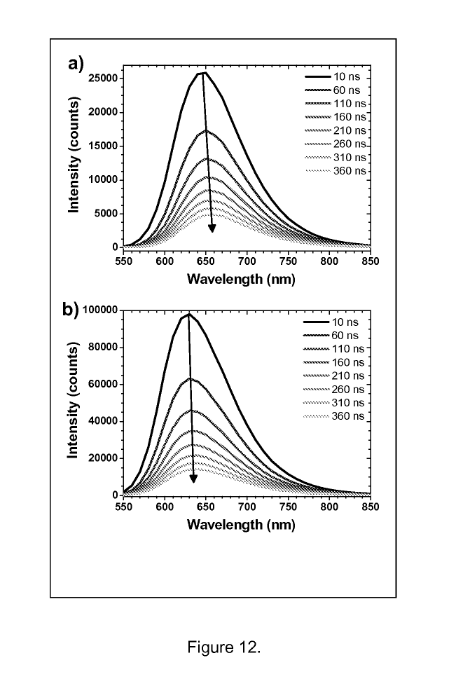

Despite the presumably equal photo excitation of both chromophores, the emission spectra of ZrO₂-1 (FIG. 11a) and ZrO₂-2 (FIG. 11b) more closely resemble the lowest energy emissive species RuP and RuP3-Zr respectively. The dominant emission from the lowest energy species can be rationalized by a −60 mV and −40 mV driving force for energy transfer from RuP3 to RuP in 1 and from RuCH₂P to RuP3 in 2 respectively. The presence of energy transfer is further supported by the time-resolved emission spectra of the bilayer films in 0.1 M HClO₄ aqueous solution (FIG. 12). Over the course of 350 ns, the emission maximum in ZrO₂-1 shifts from 646 (at 10 ns) to 659 nm (at 360 ns) (FIG. 12a). Similarly the emission maximum in ZrO₂-2 shifts from 629 (at 10 ns) to 639 nm (at 360 ns) (FIG. 12b). Assuming there is no energy transfer, it would be expected that the lower energy species would decay faster than the higher energy species in accord with the energy gap law. However, spectral shift to lower energy over time as observed in ZrO₂-1 and ZrO₂-2 indicates energy transfer from the higher energy species to the lower energy species.

### Transient Absorption.

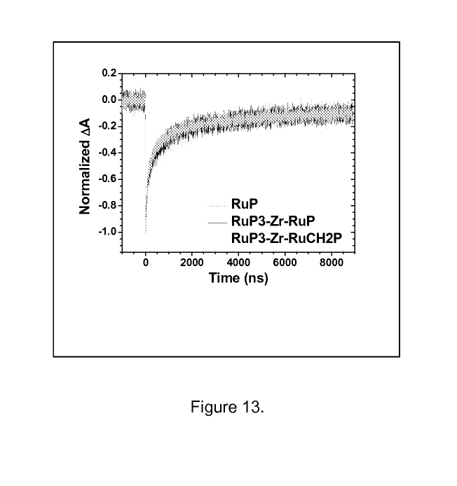

As mentioned above, electron transfer between the layers of the bilayer film can be helpful to DSSC and DSPEC operation. The electron transfer dynamics of the bilayer films were examined using transient absorption spectroscopy. Although the contribution from excited state kinetics should be relatively small, due to electron transfer quenching on TiO₂, the electron transfer kinetics were isolated following the procedure of Gillaizeau-Gauthier et al. where the ground state/excited state isosbestic point for the chromophores on ZrO₂ was used for single wavelength measurements of back electron kinetics (k_{bet}) TiO₂.³⁶ For the bilayer films, the isosbestic point for the second layer chromophore (400 nm) was chosen for single wavelength kinetics since excited state contributions from the first layer are expected to be small (<1%). Monitoring the absorption-time traces at 400 nm for ZrO₂-1 and ZrO₂-2 also indicates there is minimal (<5 mOD) excited state contribution at this wavelength. Absorption-time kinetic traces of RuP, RuCH₂P, RuP3-Zr, 1 and 2 on TiO₂ in Ar deaerated 0.1 M HClO₄ aqueous solution were collected at the ground/excited state isosbestic point following 532 nm excitation and selected results can be seen in FIG. 13.

In FIG. 13, the negative ΔA upon photo excitation is due to the Ru^{III} complex generation by electron transfer from the Ru^{II} to TiO₂. The kinetics of electron injection are not observed as they are faster than the instrument response (<10 ns). The positive shift in ΔA after excitation over the course of 10 μs measurement window corresponds to the back electron transfer from TiO₂(e⁻) to the Ru^{III} chromophore resulting in the return of Ru^{II}. As expected for sensitized TiO₂ films, the back electron transfer kinetics were non-exponential and highly complex. The data were successfully fit using a tri-exponential function (equation 1a) and the weighted average obtained from equation 1b.

k_{obs}=A₁e^{-k1t}+A₂e^{-k2t}+A₃e^{-k3t} (eq 1a)

τᵢ=1/kᵢ; <τ>=ΣAᵢtᵢ²/ΣAᵢτᵢ (eq 1b)

The kinetic parameters for back electron transfer are summarized in Table 3. The k_{bet} was found to be similar (±1 μs) in both the monolayer (RuP, RuCH₂P, RuP3-Zr) and bilayer films (1 and 2).

TABLE 3
Kinetic parameters obtained from transient absorption traces at selected
wavelengths for RuP, RuCH₂P, RuP3-Zr, 1 and 2 on TiO₂ in 0.1M
HClO₄ aqueous solution.

| | Lifetime (μs) | | | | |
|---|---|---|---|---|---|
| | τ₁ (A₁) | τ₂ (A₂) | τ₃ (A₃) | <τ> | k_{bet} (10⁴ s⁻¹) |
| RuP | 0.08(1) | 0.74(9) | 11.7(90) | 10.1 | 9.9 |
| RuCH₂P | 0.14(1) | 1.04(7) | 12.8(92) | 12.7 | 7.9 |
| RuP3-Zr | 0.10(1) | 0.93(8) | 12.1(91) | 12 | 8.3 |
| 1 | 0.07(1) | 0.82(10) | 11.9(89) | 11.7 | 8.5 |
| 2 | 0.09(1) | 1.22(16) | 10.8(82) | 10.6 | 9.4 |

Due to the strong similarity in absorption spectra for the chromophores in the bilayer film, it is difficult to selectively monitor electron transfer events between the chromophores. However, several suggestions as to the electron transfer events in the film can be inferred from the similar back electron transfer rates. Without wishing to be bound by theory, the first possibility is that upon excitation, the inside chromophore (the first molecule) undergoes electron injection but there is not electron transfer from the outside chromophore (the second molecule) to the inside. This scenario is reasonable since electron transfer from TiO₂ to an outside layer Ru^{III} is expected to be significantly slower than in the monolayer films based on distance dependence on electron transfer rates. Counter to this conclusion is the increased driving force for electron transfer from RuP to RuP3 (−100 mV) and from RuCH2P to RuP3 (−160 mV) relative to the observed energy transfer process. Presumably, the electronic coupling between the layers for electron transfer is also greater than for energy transfer. The second possibility that coincides with these observations is that electron transfer between the layers is significantly faster than electron transfer from TiO₂ to the first layer of the films. In this scenario, the back electron transfer rate to the bilayer film would resemble that of a monolayer film since the rate-limiting step in both films is the TiO₂(e⁻)-Ru^{III} to TiO₂—Ru^{II} electron transfer event. Support for fast electron transfer between the layers of the films is provided by electrochemical measurements.

### Electrochemistry.

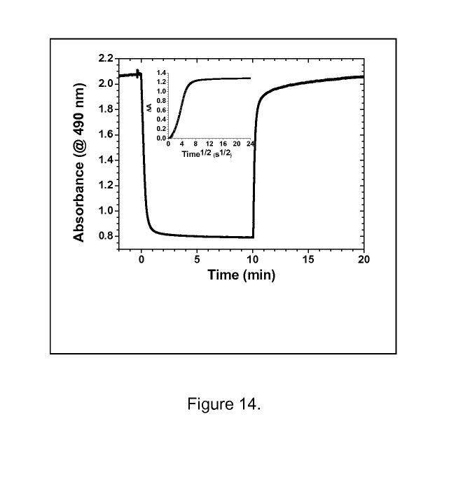

An applied potential of less than 2 V vs. Ag/AgCl to the above TiO₂ films is insufficient to oxidize nanocrystalline TiO₂. Consequently, all oxidizing events of the TiO₂ bound chromophore occurs at the ITO electrode with oxidation of ruthenium(II) complexes non-adjacent to the ITO electrode requiring thermally activated cross surface electron transfer.³⁹ The oxidation of ruthenium (II) polypyridyl complexes is accompanied by a bleach of the ¹MLCT absorption band from 400-500 nm which provides an absorptiometric means of characterizing the dynamics of surface electron transfer. In this fashion, the time-dependent absorbance changes at 490 nm of RuP, RuCH₂P, RuP3-Zr, 1 and 2 on TiO₂ in Ar deaerated 0.1 M HClO₄ aqueous solution under applied potential (1.5 V) were monitored and the results for TiO₂-1 can be seen in FIG. 14. In the experiment reported in the figure, the applied potential was stepped to 1.5 V at time zero, and stepped back to 0 V at ten minutes.

According to previously published procedures, the early time changes in absorption versus t^{1/2} (inset FIG. 14) was fit using a modified Cottrell equation (equation 2) to give the apparent charge-transfer diffusion coefficients (Dₐₚₚ) reported in Table 4.

ΔA=(2AₘₐₓDₐₚₚ^{1/2}tt^{1/2})/(dπ^{1/2}) (eq 2)

In eq 2, ΔA is the change in absorbance at time t, Aₘₐₓ is the absorbance at t=0 and d is the film thickness (4.5 μm).

TABLE 4
The cross surface diffusion coefficient for RuP, RuCH₂P,
RuP3-Zr, 1 and 2 on TiO₂ in 0.1M HClO₄ aqueous solution.

| | Dₐₚₚ × 10⁻¹⁰ |
|---|---|
| Complex | (cm²/s) |
| RuP | 13.3 |
| RuCH₂P | 12.1 |
| RuP3-Zr | 1.8 |
| 1 | 28.5 |
| 2 | 26.0 |

Interestingly, the apparent charge-transfer diffusion coefficient for the bilayer films 1 and 2 (>26.0×10⁻¹⁰ cm²/s) are two times larger than for the monolayer films of RuP and RuCH₂P (<13.3×10⁻¹⁰ cm²/s) and an order of magnitude larger than the RuP3-Zr monolayer (1.8×10⁻¹⁰ cm²/s) on TiO₂. If the layers of the bilayer film were to undergo cross surface electron transfer independent of one another, a biphasic change in absorption would be expected in the absorptiometric measurement with Dₐₚₚs of 1.8 and 13.3×10⁻¹⁰ cm²/s for TiO₂-1 for example. However we find that the cross surface diffusion of the bilayer film is larger than either of the components independently. According to Marcus theory, low reorganizations energies and more importantly, strong overlap of adjacent donor and acceptor molecular orbitals are necessary for high electron transfer rates. The larger Dₐₚₚ and thus higher cross surface electron transfer rate is indicative of high electronic coupling of the bilayer films. This result supports the hypothesis that the fast electron transfer between the bilayers is in fact responsible for the similar back electron transfer rates between monolayer and bilayer films as discussed above.

The two-fold increase in Dₐₚₚ for the bilayer films indicates that the cross surface electron transfer is not limited by the fastest monolayer pathway but instead is the result of the layers working in concert. The measured Dₐₚₚ is not a site-to-site hopping rate but instead a bulk property of the surface which includes open sights, bottle necks and other inhomogeneities associated with chromophore deposition. For a monolayer film, these defects hinder cross surface electron transfer. On the other hand, the bilayer film offers a second alternative pathway for electron transfer effectively avoiding the above-mentioned defects.

### Photostability.

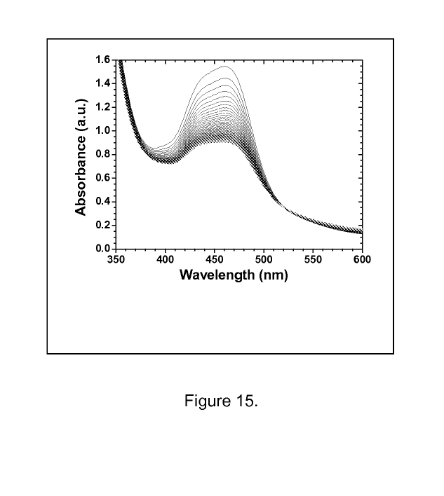

The photostability of RuP, RuCH₂P, 1 and 2 on TiO₂ in Ar deaerated 0.1 M HClO₄ aqueous solution were measured according to previously published procedure using 455 nm constant irradiation (FWHM ˜30 nm, 475 mW/cm²). The changes in absorption spectra over 16 hours were monitored every 15 min and the results for 1-TiO₂ can be seen in FIG. 15 (black trace was taken first; gray trace was taken last). As noted in our previous report, the disappearance of the MLCT transition in aqueous solutions can be attributed to desorption of the chromophore from the TiO₂ surface. The absorption-time traces at 480 nm could be satisfactorily fit with the biexponential function and are represented by a single rate constant (k_{des}) by calculating the weighted average lifetime (<τ>) with the results summarized in Table 5. Comparable photostability was observed for the monolayer and bilayer films.

TABLE 5
The photostability of RuP, RuCH₂P, RuP3-Zr, 1 and 2 on
TiO₂ in 0.1M HClO₄ aqueous solution.

| | k_{des} × 10⁻⁵ (s⁻¹) |
|---|---|
| RuP | 5.0 |
| RuCH₂P | 5.8 |
| RuP3-Zr | 3.5 |
| 1 | 6.6 |
| 2 | 6.4 |

### Other Chromophore Bilayer Films.

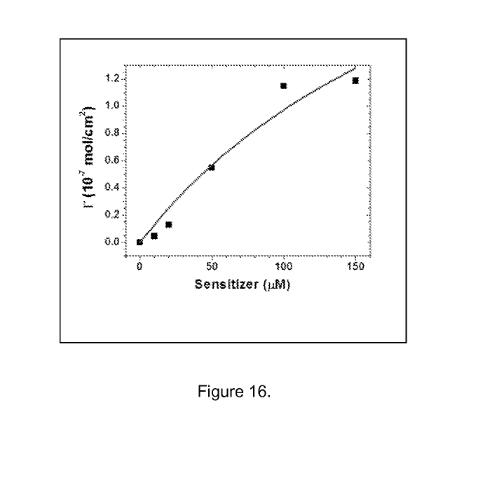

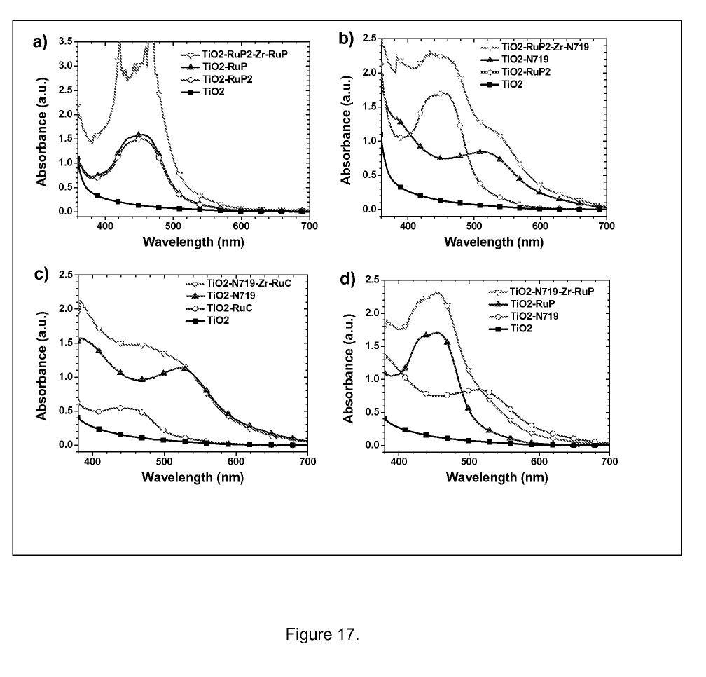

The above discussion focuses on RuP3 as the first layer with RuP and RuCH₂P as the outside layer. However, our preliminary results indicate that the library of bilayer films with various chromophores is accessible using this technique. For example, the bis-phosphonated complex (RuP2) can also act as the first layer of the film. The absorption spectra for the monolayers of RuP, RuP2 and the bilayer of RuP2-Zr—RuP on TiO₂ can be seen in FIG. 17a. As expected for the bilayer film, the absorption of RuP2-Zr—RuP is approximately the sum of RuP and RuP2 monolayers on TiO₂. From the adsorption isotherm at 532 nm (FIG. 16), it was found that the maximum surface coverage (2.4×10⁻⁷ mol cm⁻²) and adduct formation constant (4,000 M⁻¹) for RuP on TiO₂—RuP2-Zr were similar to those found on TiO₂—RuP3-Zr (Table 1). Presumably, the coordination of Zr⁴⁺ to the two non-surface-bound phosphonate groups of RuP2 provides sufficient binding sites for the coordination of the second layer, which contains RuP.

The self-assembled bilayer strategy can also be expanded to include carboxylated chromophore like RuC and N719. As can be seen in FIG. 17 the bilayer films of TiO₂—RuP2-Zr—N719 (FIG. 17b) and TiO₂—N719-Zr—RuC (FIG. 17c) have absorbance spectra that approximately equal to the sum of the monolayer chromophores on TiO₂. It must be noted that due to the relatively fast desorption of carboxylated complexes in aqueous conditions, all films of RuC and N719 as well as ZrOCl₂ deposition on top of N719 were performed from methanol to prevent desorption. The results in FIG. 17 indicate the deposition orders like phosphonate-Zr-phosphonate, phosphonate-Zr-carboxylate and carboxylate-Zr-carboxylate are feasible for bilayer film formation on nanocrystalline metal oxides. However, attempts at carboxylate-Zr-phosphonate deposition using N719-Zr—RuP did not result in a bilayer absorption spectrum equal to the sum of the monolayer films. See FIG. 17d. The decreased absorption of the bilayer film compared to the N719 from 520 to 700 nm suggests at least partial desorption of the N719 dye upon soaking in the RuP methanol solution. Presumably, the higher binding affinity of TiO₂ for the phosphonates of RuP, compared to the carboxylates of N719, results in competitive binding and partial desorption of the N719 layer. An alternative solvent choice or loading time may alleviate this issue.

### Chromophore-Catalyst Bilayer Films.

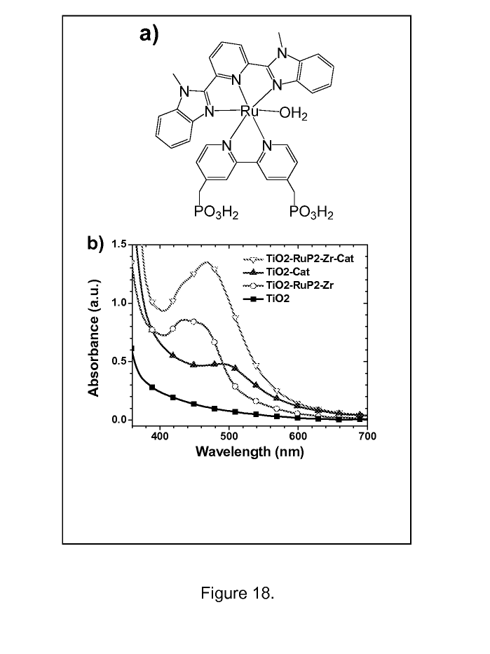

The self-assembly strategy can readily be expanded to include chromophore-Zr-catalyst bilayer films. The single site water oxidation catalyst [Ru(2,6-bis(1-methylbenzimidazol-2-yl)pyridine)(4,4′-CH₂PO₃H₂-bpy)(OH₂)]²⁺ (Cat; FIG. 18a) was chosen to demonstrate bilayer film formation particularly for its potential application in water oxidation DSPECs. Similar to the two-chromophore systems, the TiO₂—RuP2-Zr-Cat film exhibits absorption approximating the sum of the monolayer films of RuP2 and Cat on TiO₂ (FIG. 18b).

In some embodiments of a DSPEC photoanode, comprising a chromophore and catalyst on an n-type semiconducting material like TiO₂, photoexcitation of the chromophore results in excited state electron transfer into the high surface area semiconductor. The now-electron deficient chromophore has sufficient oxidizing strength to result in electron transfer from the catalyst to the chromophore. This process is repeated several more times (four times total for water oxidation) to build up the redox equivalents necessary for a catalytic reaction. The key to the operation of these devices in some embodiments is that the oxidized state remains on the catalyst rather than the chromophore.

Transient absorption spectroscopy was used to investigate the preliminary steps in DSPEC operation, namely 1) photoexcitation, 2) electron injection, 3) electron transfer and 4) back electron transfer to the oxidized catalyst using a bilayer film composed of TiO₂—RuP2-Zr-Cat. The kinetics of electron injection and electron transfer are not observed as they are faster than the instrument response (<10 ns) so the discussion below will exclusively focus on the species and events that occur after 10 ns.

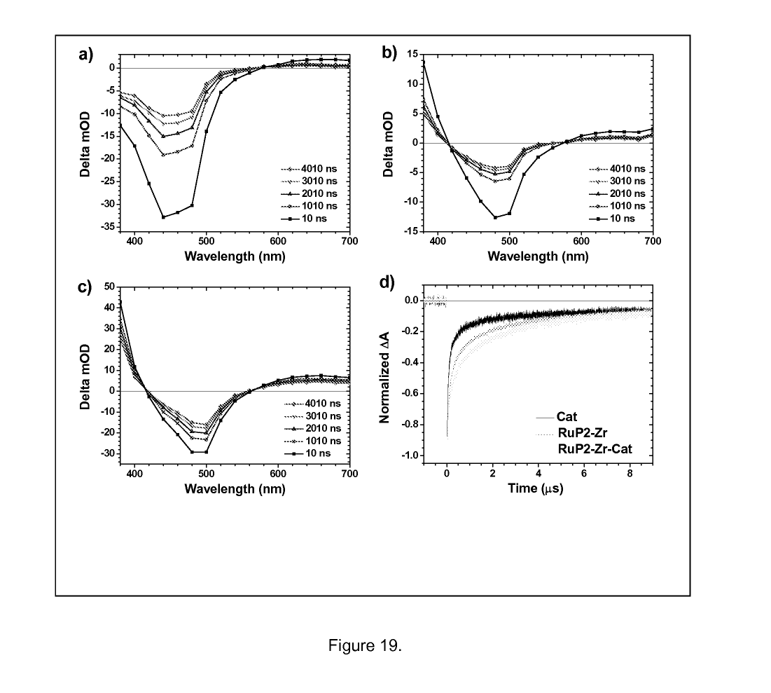

Time-resolved absorption difference spectra of RuP2-Zr, Cat and RuP2-Zr-Cat on TiO₂ in Ar deaerated 0.1 M HClO₄ aqueous solution were constructed from multiple single-wavelength measurements (532 nm excitation with 10 nm steps from 380-780 nm). As can be seen in FIG. 19, TiO₂—RuP2-Zr (FIG. 19a) exhibits an absorption difference spectrum typical for ruthenium polypyridyl complexes on TiO₂, a negative ΔOD from 380 to 580 nm attributed to the bleach of the ruthenium (II) ¹MLCT absorption band. Also observed is a positive signal from 580 to 800 nm which is due to the generation of Ru^{III} upon electron injection. Similar characteristics are observed for TiO₂-Cat (FIG. 19b), a Ru^{III} signal from 580 to 800 nm and a bleach associated with the disappearance of ruthenium (II) ¹MLCT absorption. However the high energy onset of the ¹MLCT bleach for TiO₂-Cat is slightly red-shifted (415 nm) relative to TiO₂—RuP2-Zr (380 nm). Additionally a positive peak from 380 to 415 nm is observed in TiO₂-Cat that is not present in TiO₂—RuP2-Zr. The difference spectrum of the bilayer film, TiO₂—RuP2-Zr-Cat (FIG. 19c), is qualitatively similar in both peak position and isosbestic point to that of TiO₂-Cat. The similarity in spectra suggests that the oxidized species in the bilayer system is the catalyst. The formation of Cat+ is likely the result of either remote electron injection from excited Cat to TiO₂ or electron injection from the chromophore into TiO₂ followed by electron transfer from Cat to Ru^{III}P2-Zr. Regardless of the mechanism, the oxidized species being located remotely to the surface appears to decrease the rate of back electron transfer.

The single wavelength kinetics (at 480 nm with 532 nm excitation) over a 10 μs window (FIG. 19d) corresponds to the back electron transfer from TiO₂(e⁻) to the Ru^{III} chromophore or catalyst resulting in the return of Ru^{II}. The time required for 50% of the initial negative signal to decay to 0 (t_{1/2}) increases in the order of Cat (55 ns) to RuP2-Zr (175 ns) to RuP2-Zr-Cat (240 ns). The relatively slow back electron transfer to the Cat in the bilayer film, relative to the monolayer films, indicates either the slow electron transfer from spatially separated TiO₂ to the oxidized Cat or the slow electron transfer from RuP2 to Cat followed by electron transfer from TiO₂ to the oxidized RuP2.

Various embodiments of the invention have been described. It should be recognized that these embodiments are merely illustrative of the principles of the present invention. Furthermore, the foregoing description of various embodiments does not necessarily imply exclusion. For example, “some” embodiments may include all or part of “other” and “further” embodiments. Numerous modifications and adaptations thereof will be readily apparent to those skilled in the art without departing from the spirit and scope of the invention.

The patents, patent applications, and articles mentioned or cited herein are hereby incorporated by reference in their entireties as if fully set forth herein.

### REFERENCES

1. A. Hagfeldt, G. Boschloo, L. Sun, L. Kloo and H. Pettersson, Chem. Rev., 2010, 110, 6595-6663.
2. T. J. Meyer, J. M. Papanikolas and C. M. Heyer, Catal. Lett., 2011, 141, 1-7.
3. B. O'Regan and M. Gratzel, Nature, 1991, 353, 737-740.
4. A. Yella, H.-W. Lee, H. N. Tsao, C. Yi, A. K. Chandiran, M. K. Nazeeruddin, E. W.-G. Diau, C.-Y. Yeh, S. M. Zakeeruddin and M. Grätzel, Science, 2011, 334, 629-634.
5. W. Song, C. R. K. Glasson, H. Luo, K. Hanson, M. K. Brennaman, J. J. Concepcion and T. J. Meyer, J. Phys. Chem. Lett., 2011, 2, 1808-1813.
6. R. Argazzi, C. A. Bignozzi, T. A. Heimer and G. J. Meyer, Inorganic Chemistry, 1997, 36, 2-3.
7. A. C. Lees, C. J. Kleverlaan, C. A. Bignozzi and J. G. Vos, Inorganic Chemistry, 2001, 40, 5343-5349.
8. C. Kleverlaan, M. Alebbi, R. Argazzi, C. A. Bignozzi, G. M. Hasselmann and G. J. Meyer, Inorganic Chemistry, 2000, 39, 1342-1343.
9. C. J. Kleverlaan, M. T. Indelli, C. A. Bignozzi, L. Pavanin, F. Scandola, G. M. Hasselman and G. J. Meyer, Journal of the American Chemical Society, 2000, 122, 2840-2849.
10. S. H. Wadman, Y. M. van Leeuwen, R. W. A. Havenith, G. P. M. van Klink and G. van Koten, Organometallics, 2010, 29, 5635-5645.
11. T. Rawling, C. Austin, F. Buchholz, S. B. Colbran and A. M. McDonagh, Inorganic Chemistry, 2009, 48, 3215-3227.
12. Y. Lee, S.-R. Jang, R. Vittal and K.-J. Kim, New Journal of Chemistry, 2007,
13. H. Lee, L. J. Kepley, H. G. Hong, S. Akhter and T. E. Mallouk, The Journal of Physical Chemistry, 1988, 92, 2597-2601.
14. H. Lee, L. J. Kepley, H. G. Hong and T. E. Mallouk, Journal of the American Chemical Society, 1988, 110, 618-620.
15. H. J. Chae, M. S. Lee, Y. I. Kim and H. Lee, Bulletin of the Korean Chemical Society, 1998, 19, 27-29.
16. M. A. Rodrigues, D. F. S. Petri, M. J. Politi and S. Brochsztain, Anais da Academia Brasileira de Ciências, 2000, 72, 75-78.
17. G. A. Neff, M. R. Helfrich, M. C. Clifton and C. J. Page, Chemistry of Materials, 2000, 12, 2363-2371.
18. V. Spampinato, N. Tuccitto, S. Quici, V. Calabrese, G. Marietta, A. Torrisi and A. Licciardello, Langmuir, 2010, 26, 8400-8406.
19. K. Terada, K. Kobayashi, J. Hikita and M.-a. Haga, Chemistry Letters, 2009, 38, 416-417.
20. T. Ishida, K.-i. Terada, K. Hasegawa, H. Kuwahata, K. Kusama, R. Sato, M. Nakano, Y. Naitoh and M.-a. Haga, Applied Surface Science, 2009, 255, 8824-8830.
21. K. Hu, R. Pyati and A. J. Bard, Analytical Chemistry, 1998, 70, 2870-2875.
22. S. B. Bakiamoh and G. J. Blanchard, Langmuir, 1999, 15, 6379-6385.
23. M. Brust, P. M. Blass and A. J. Bard, Langmuir, 1997, 13, 5602-5607.
24. M. A. Ansell, E. B. Cogan and C. J. Page, Langmuir, 1999, 16, 1172-1179.
25. Y.-g. Ha, A. Facchetti and T. J. Marks, Chemistry of Materials, 2009, 21, 1173-1175.
26. M. P. Danahy, M. J. Avaltroni, K. S. Midwood, J. E. Schwarzbauer and J. Schwartz, Langmuir, 2004, 20, 5333-5337.
27. M. S. Lee, H. K. Shim and Y. I. Kim, Molecular Crystals and Liquid Crystals Science and Technology. Section A. Molecular Crystals and Liquid Crystals, 1998, 316, 401-406.
28.1. Gillaizeau-Gauthier, F. Odobel, M. Alebbi, R. Argazzi, E. Costa, C. A. Bignozzi, P. Qu and G. J. Meyer, Inorganic Chemistry, 2001, 40, 6073-6079.
29. S.-H. A. Lee, N. M. Abrams, P. G. Hoertz, G. D. Barber, L. I. Halaoui and T. E. Mallouk, J. Phys. Chem. B, 2008, 112, 14415-14421.
30. M. K. Brennaman, A. O. T. Patrocinio, W. Song, J. W. Jurss, J. J. Concepcion, P. G. Hoertz, M. C. Traub, N. Y. Murakami Iha and T. J. Meyer, ChemSusChem, 2011, 4, 216-227.
31. L. A. Gallagher, S. A. Serron, X. Wen, B. J. Hornstein, D. M. Dattelbaum, J. R. Schoonover and T. J. Meyer, Inorg. Chem., 2005, 44, 2089-2097.
32. K. M. Omberg, J. R. Schoonover, J. A. Treadway, R. M. Leasure, R. B. Dyer and T. J. Meyer, Journal of the American Chemical Society, 1997, 119, 7013-7018.
33.1. Maege, E. Jaehne, A. Henke, H.-J. P. Adler, C. Bram, C. Jung and M. Stratmann, Progress in Organic Coatings, 1997, 34, 1-12.
34. T. Undabeytia, E. Morillo and C. Maqueda, Journal of Agricultural and Food Chemistry, 2002, 50, 1918-1921.
35. W. Gao, L. Dickinson, C. Grozinger, F. G. Morin and L. Reven, Langmuir, 1996, 12, 6429-6435.
36.1. Gillaizeau-Gauthier, F. Odobel, M. Alebbi, R. Argazzi, E. Costa, C. A. Bignozzi, P. Qu and G. J. Meyer, Inorg. Chem., 2001, 40, 6073-6079.
37. S. Ardo and G. J. Meyer, Chem. Soc. Rev., 2009, 38, 115-164.
38. J. R. Durrant, S. A. Hague and E. Palomares, Coordination Chemistry Reviews, 2004, 248, 1247-1257.
39. P. Bonhôte, E. Gogniat, S. Tingry, C. Barbé N. Vlachopoulos, F. Lenzmann, P. Comte and M. Grätzel, The Journal of Physical Chemistry B, 1998, 102, 1498-1507.
40. S. A. Trammell and T. J. Meyer, J. Phys. Chem. B, 1999, 103, 104-107.
41. B. C. Lin, C. P. Cheng, Z.-Q. You and C.-P. Hsu, Journal of the American Chemical Society, 2004, 127, 66-67.
42. D. Wang, R. Mendelsohn, E. Galoppini, P. G. Hoertz, R. A. Carlisle and G. J. Meyer, J. Phys. Chem. B, 2004, 108, 16642-16653.
43. Q. Zhang, C. S. Dandeneau, X. Zhou and G. Cao, Advanced Materials, 2009, 21, 4087-4108.
44. K. J. Gagnon, H. P. Perry and A. Clearfield, Chemical Reviews, 2011.
45. J. C. Horne and G. J. Blanchard, J. Am. Chem. Soc. 1999, 121, 4427-4432.
46. H. Nusbaumer, J.-E. Moser, S. M. Zakeeruddin, M. K. Nazeeruddin, and M. Gratzel, J. Phys. Chem. B 2001, 105, 10461-10464.

47. H. Choi, S. Kim, S. O. Kang, J. Ko, M.-S. Kang, J. N. Clifford, A. Formeli, E. Palomares, M. K. Nazeeruddin, and M. Gratzel, Angew. Chem. 2008, 120, 8383-8387.
48. Y. Liu, J. R. Jennings, Y. Huang, Q. Wang, S. M. Zakeeruddin, and M. Gratzel, J. Phys. Chem. C 2011, 115, 18847-18855.
49. A. Yella, H.-W. Lee, H. N. Tsao, C. Yi, A. K. Chandiran, M. K. Nazeeruddin, E. W.-G. Diau, C.-Y. Yeh, S. M. Zakeeruddin, and M. Gratzel, Science 2011, 334, 629-634.
50. H.-G. Hong, D. D. Sackett, and T. E. Mallouk, Chem. Mater. 1991, 3, 521-527.
51. G. Cao, H.-G. Hong, and T. E. Mallouk, Acc. Chem. Res. 1992, 25, 420-427.
52. M. P. Danahy, M. J. Avaltroni, K. S. Midwood, J. E. Schwarzbauer, and J. Schwartz, Langmuir 2004, 20, 5333-5337.
53. S. W. Gersten, G. J. Samuels, and T. J. Meyer, J. Am. Chem. Soc. 1982, 104, 4029-4030.
54. K. Hanson, M. K. Brennaman, H. Luo, C. R. K. Glasson, J. J. Concepcion, W. Song, and T. J. Meyer, ACS App. Mater. Interfaces 2012, ______, ______ (published online Feb. 8, 2012 at: http://pubs.acs.org/doi/pdf/10.1021/am201717x).

1. An assembly for harvesting light, comprising:
a surface comprising a metal oxide and having a high surface area;
a first molecule linked to the surface through a surface-linking group,
wherein the first molecule is a chromophore; and
a second molecule,
wherein the second molecule is chosen from chromophores, catalysts, and redox mediators;
wherein the first molecule and the second molecule are joined via mutual coordination to an ion.

2. The assembly of claim 1, wherein the first molecule and second molecule are chosen so that incident light will induce excited state electron transfer into the metal oxide.

3. The assembly of claim 1, wherein the first molecule and second molecule are chosen so that incident light will induce excited state electron transfer from the metal oxide.

4. The assembly of claim 1, wherein the first molecule and the second molecule are chosen so that incident light will induce oxidation, reduction, or catalytic reaction of a species in reactive communication with the assembly.

5. The assembly of claim 1, wherein at least some of the metal oxide is in the form of nanoparticles, nanocrystals, nanocolumns, nanotubes, nanosheets, nanoscrolls, nanowires, nanotips, nanoflowers, nanohorns, nano-onions, dendritic nanowires, or a combination of two or more thereof.

6. The assembly of claim 1, wherein the metal oxide is chosen from SnO₂, TiO₂, Nb₂O₅, SrTiO₃, ZnO, Zn₂SnO₄, ZrO₂, NiO, Ta-doped TiO₂, Nb-doped TiO₂, and combinations of two or more thereof.

7. The assembly of claim 1, wherein the metal oxide comprises core-shell nanostructures comprising one or more of: ZnO-coated SnO₂, MgO-coated SnO₂, Al₂O₃-coated SnO₂, TiO₂-coated In-doped SnO₂, and TiO₂-coated F-doped SnO₂.

8. The assembly of claim 1, wherein the ion is chosen from Cu²⁺, Co²⁺, Ni²⁺, Zn²⁺, Mn²⁺, Fe²⁺, Sr²⁺, Al³⁺, V³⁺, In³⁺, Fe³⁺, Gd³⁺, Y³⁺, Yb³⁺, Nd³⁺, Ce³⁺, La³⁺, Sc³⁺, Dy³⁺, Zr⁴⁺, Ti⁴⁺, Se, and combinations thereof.

9. The assembly of claim 1, wherein the surface linking group is chosen from
—COOH, —PO₃H₂, —SO₃H, —OPO₃H, —OSO₃H, —SiR₃, -Ph(OH)₂, —CH(CO₂H)₂, —CH═C(CO₂H)₂, —CONHOH, —CSSH, —CSOH, and combinations thereof.

10. The assembly of claim 1, wherein the mutual coordination of an ion is accomplished by alike or different ion coordination groups chosen from:
—COOH, —PO₃H₂, —SO₃H, —OPO₃H, —OSO₃H, —SiR₃, -Ph(OH)₂, —CH(CO₂H)₂, —CH═C(CO₂H)₂, —CONHOH, —CSSH, —CSOH, and combinations thereof.

11. The assembly of claim 1, further comprising:
a third molecule,
wherein the third molecule is chosen from chromophores, catalysts, and redox mediators;
wherein the second molecule and the third molecule are joined via mutual coordination to an ion.

12. The assembly of claim 11, wherein the ion joining the second and third molecule is of the same identity as the ion joining the first and second molecule.

13. The assembly of claim 1, wherein any one of the first molecule and the second molecule is chosen from ruthenium coordination complexes, osmium coordination complexes, copper coordination complexes, porphyrins, phthalocyanines, and organic dyes, and combinations thereof.

14. The assembly of claim 13, wherein ruthenium coordination complexes are chosen from: 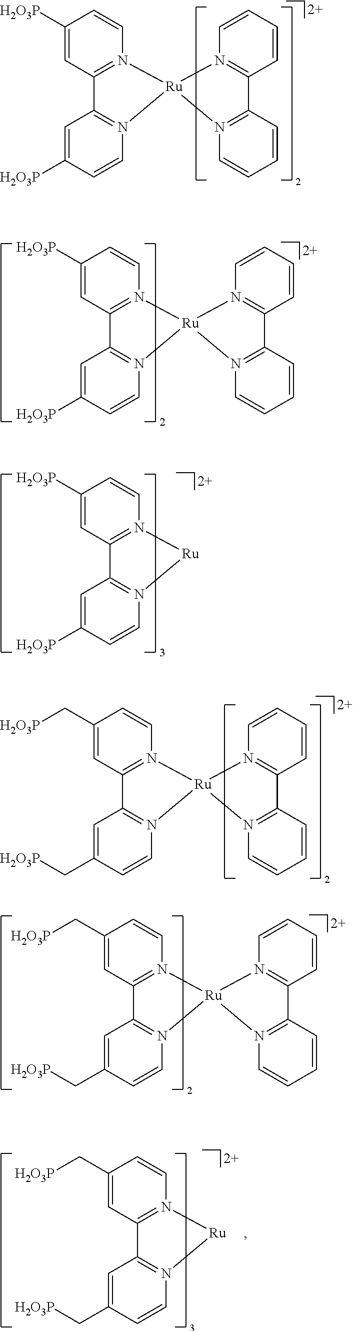 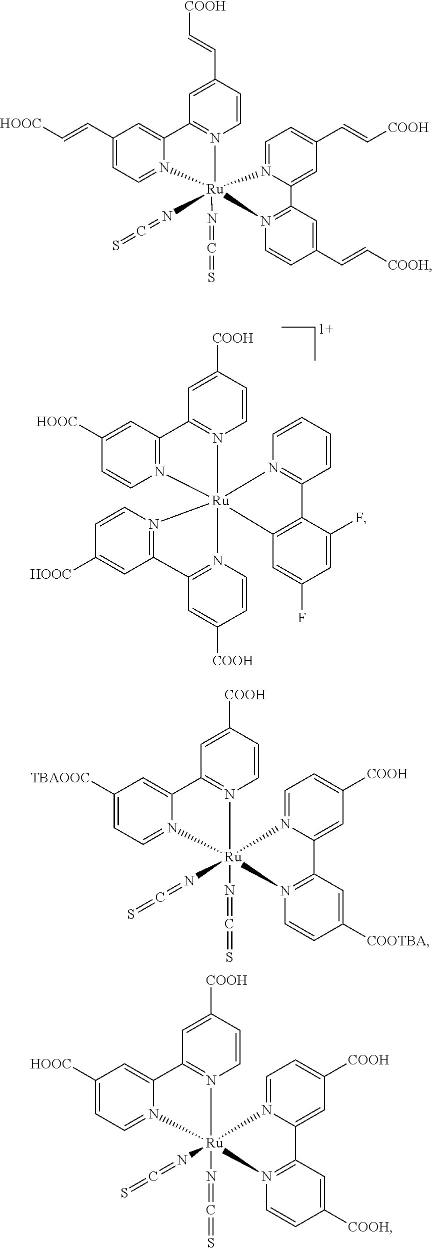 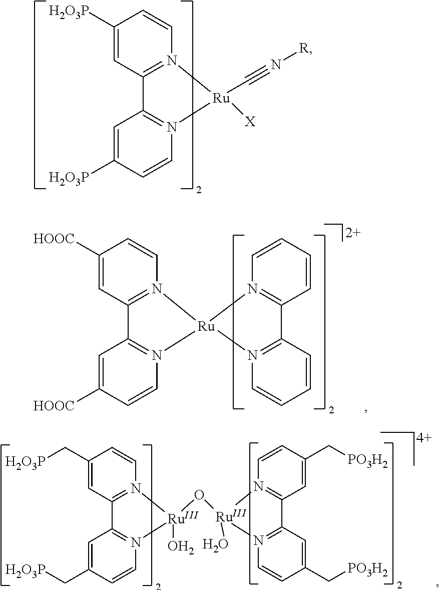
deprotonated derivatives of any of the foregoing;
and combinations thereof.

15. The assembly of claim 13, wherein the ruthenium coordination complexes are chosen from (X)₂bis(2,2′-bipyridyl-4,4′-dicarboxylate)ruthenium(II) compounds, wherein X is chosen from Cl, Br, I, CN, NC-Ph, and SCN; deprotonated derivatives thereof; and combinations thereof.

16. The assembly of claim 13, wherein the osmium coordination complexes are chosen from: 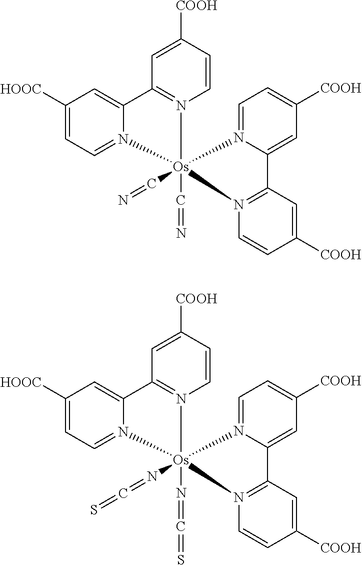
deprotonated derivatives thereof, and combinations thereof.

17. The assembly of claim 13, wherein the copper coordination complexes are chosen from: 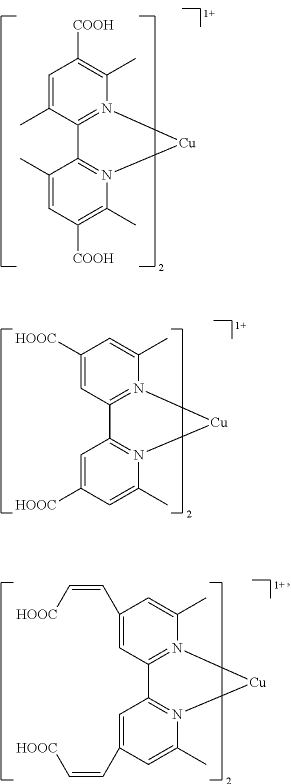
deprotonated derivatives thereof, and combinations thereof.

18. The assembly of claim 13, wherein the porphyrins are chosen from:
metal-coordination complexes comprising one of the following ligands: 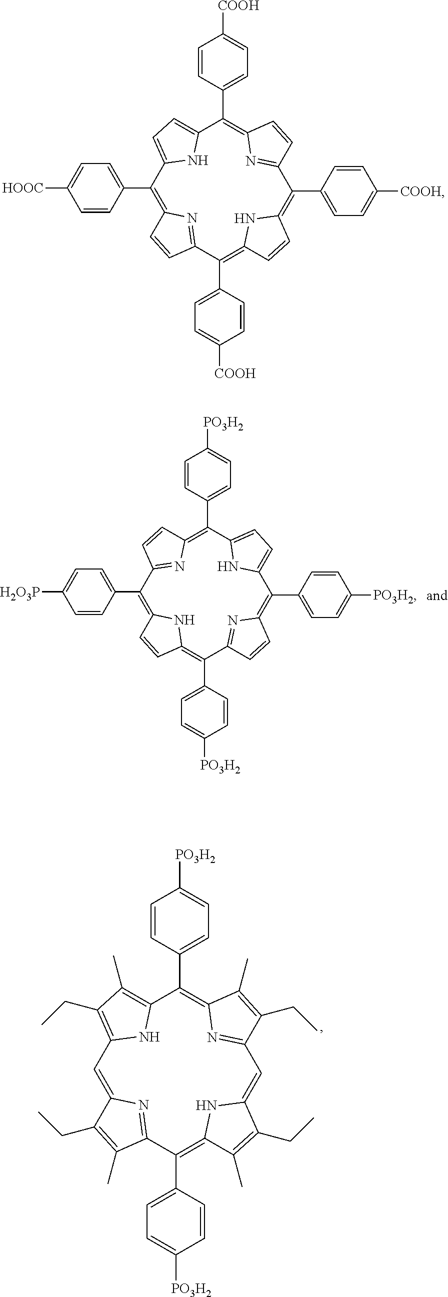
and
deprotonated derivatives thereof;
and combinations thereof.

19. The assembly of claim 13, wherein the porphyrins are chosen from compounds having the formula 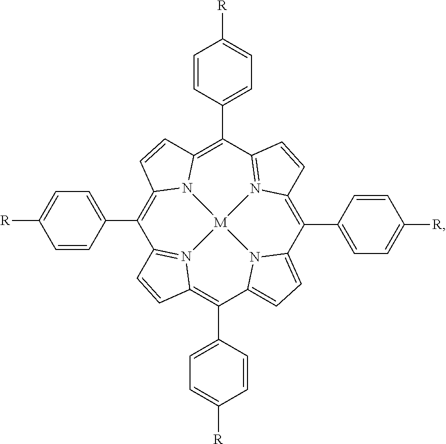
and M is Ni, Zn, Pd, Pb, Pt, or Ru, and R is chosen from —COOH, —PO₃H₂, and combinations thereof,
deprotonated derivatives thereof, and combinations thereof.

20. The assembly of claim 13, wherein the porphyrin is chosen from 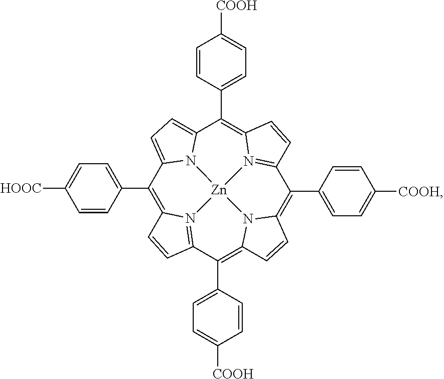
deprotonated derivatives thereof, and combinations thereof.

21. The assembly of claim 13, wherein the phthalocyanines are chosen from: 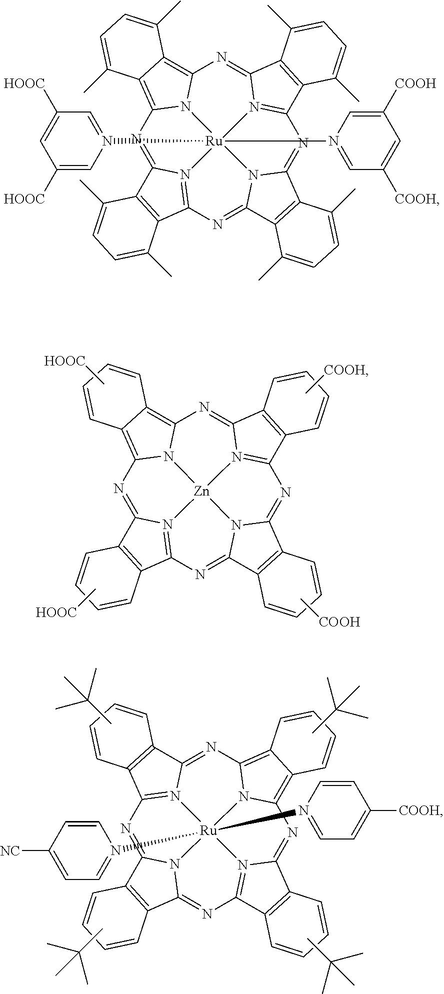
deprotonated derivatives thereof, and combinations thereof.

22. The assembly of claim 13, wherein the organic dyes are chosen from: 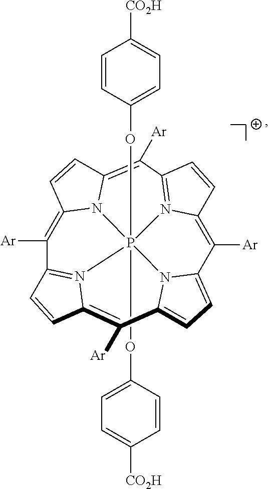
wherein Ar is 3,5-di-tertbutylphenyl; 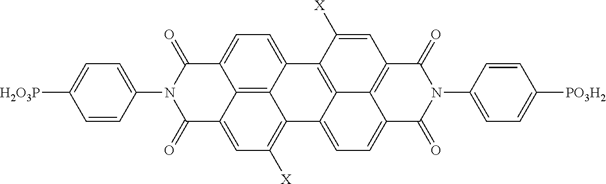
wherein X is halide, —CN, —CF₃, —CH₃, -Ph(CF₃)₂, Ph, Ph(CH₃)₂, or a combination thereof;
deprotonated derivatives thereof; and combinations thereof.

23.-49. (canceled)
